(19) United States
(12) Patent Application Publication
(10) Pub. No.: US 2013/0105762 A1
(43) Pub. Date: May 2, 2013

(54) NITRIDE SEMICONDUCTOR LIGHT EMITTING DEVICE, METHOD OF FABRICATING NITRIDE SEMICONDUCTOR LIGHT EMITTING DEVICE

(71) Applicants: Takashi KYONO, Osaka (JP); Yohei ENYA, Itami-shi (JP); Masaki UENO, Itami-shi (JP)

(72) Inventors: Takashi KYONO, Osaka (JP); Yohei ENYA, Itami-shi (JP); Masaki UENO, Itami-shi (JP)

(73) Assignee: SUMITOMO ELECTRIC INDUSTRIES, LTD., Osaka-shi (JP)

(21) Appl. No.: 13/588,746

(22) Filed: Aug. 17, 2012

(30) Foreign Application Priority Data
Nov. 2, 2011 (JP) P2011-241523

(51) Int. Cl. H01L 33/06; H01L 21/66; H01L 33/32

(52) U.S. Cl. 257/13; 438/47; 438/16; 257/E33.008; 257/E33.025; 257/E21.521

(57) ABSTRACT

A nitride semiconductor light-emitting device includes a support base and a diode structure. The support base has a primary surface of a hexagonal nitride semiconductor. The diode structure is provided on the primary surface of the support base. The diode structure includes a first conductivity type group-III nitride semiconductor layer provided on the primary surface of the support base, a light-emitting layer provided on the first conductivity type group-III nitride semiconductor layer, and a second conductivity type group-III nitride semiconductor layer provided on the light-emitting layer. The light-emitting layer has a multiple quantum well structure including first and second well layers and a barrier layer. The thickness of the barrier layer is 4.5 nm or less. The primary surface of the support base tilts at a tilt angle in the range of 50 to 80 degrees or 130 to 170 degrees from a c-plane of the hexagonal nitride semiconductor.

### BACKGROUND OF THE INVENTION

1. Field of the Invention

The present invention relates to a nitride semiconductor light-emitting device.

2. Related Background Art

Patent Literature 1 discloses a technology for improving the injection and diffusion of holes in a quantum well structure (an MQW structure or SQW structure) of a light-emitting device to enhance the luminous efficiency.

Patent Literature 2 discloses a method of fabricating a semiconductor light-emitting device, the method involves selection of an appropriate direction of piezoelectric polarization in an active layer.

Patent Literature 3 discloses a nitride-based semiconductor light-emitting device including a well layer into which carriers are effectively injected.

Non-patent Literature 1 discloses an LED having a multiple quantum well structure that generates a blue-green laser beam. Non-patent Literature 2 discloses an LD having a multiple quantum well structure that generates a green laser beam.
Patent Literature 1: Japanese Publication Unexamined Patent Application Publication No. 2002-270894
Patent Literature 2: Japanese Publication Unexamined Patent Application Publication No. 2011-77395
Patent Literature 3: Japanese Publication Unexamined Patent Application Publication No. 2011-40709

### [Non-Patent Literature]

Non-patent Literature 1: “Characterization of Blue-green m-plane InGaN Light Emitting Diodes,” You-Da Lin, Arpan Chakraborty, Stuart Brinkley, Hsun Chih Kuo, Thiago Melo, Kenji Fujito, James S. Speck, Steven P. DenBaars, and Shuji Nakamura, Applied Physics Letters 94, 261108 (2009).
Non-patent Literature 2: “High Quality InGaN/AlGaN Multiple Quantum Wells for Semipolar InGaN Green Laser Diodes,” You-Da Lin, Shuichiro Yamamoto, Chia-Yen Huang, Chia-Lin Hsiung, Feng Wu, Kenji Fujito, Hiroaki Ohta, James S. Speck, Steven P. DenBaars, and Shuji Nakamura, Applied Physics Express 3, (2010) 082001.

### SUMMARY OF THE INVENTION

In a light-emitting layer having an MQW structure in Patent Literature 1, the MQW structure is formed such that at least two of the barrier layers in the MQW structure have band gaps different from each other or preferably their band gaps gradually decrease from the p-side region to the n-side region, so that holes readily move a large distance in the MQW structure in the direction from the p-type semiconductor layer toward the n-type semiconductor layer. In a light-emitting layer having an SQW structure, the barrier layer closer to the p-side region have graded compositions such that the band gap decreases in the direction from the p-side region to the n-side region.

According to Patent Literature 2, the photoluminescence of substrate products is measured while a bias is applied to the substrate products to determine the bias dependency of the photoluminescence spectrums of the substrate products, and quantum well structures for a light-emitting layer, and p-type and n-type gallium nitride semiconductor layers are grown on the substrates of one or more selected tilt angles to form the substrate products. Based on the bias dependency, the direction of piezoelectric polarization in the light-emitting layer is estimated at the selected tilt angles of the substrate primary surface. Based on the estimation, whether a tilt angle corresponding to the primary surface or the back face of the substrate should be used is determined to select the plane orientation of the substrate for growth for fabrication of a semiconductor light-emitting device. Semiconductor layers for the semiconductor light-emitting device are grown on the primary surface of the growth substrate.

The nitride semiconductor light-emitting device disclosed in Patent Literature 3 includes a substrate composed of a hexagonal gallium nitride-based semiconductor, an n-type gallium nitride-based semiconductor region on the primary surface of the substrate, a light-emitting layer having a single quantum well structure on the n-type gallium nitride-based semiconductor region, and a p-type gallium nitride-based semiconductor region on the light-emitting layer. The light-emitting layer is disposed between the n-type gallium nitride-based semiconductor region and the p-type gallium nitride-based semiconductor region, and includes a well layer and a barrier layer. The well layer is composed of InGaN. The primary surface of the substrate extends along the reference plane that tilts at a tilt angle within the range of 63 to 80 degrees or 100 to 117 degrees from a plane orthogonal to the c-axis of the hexagonal gallium nitride-based semiconductor.

The LED disclosed in Non-patent Literature 1 is formed on the m-plane. The LD disclosed in Non-patent Literature 2 is formed on the (20-21) plane.

Various quantum well structures are described in Patent Literatures 1, 2, and 3, and Non-patent Literatures 1 and 2. The strain and polarity of a quantum well structure on a semipolar surface differs from those of a quantum well structure on the c-plane. Such difference in property between these quantum well structures cause the band structure of the quantum well structures on the semipolar surface to incorporate strain different from that in the c-plane. Thus, the quantum well structure on a semipolar surface may have low electron injection efficiency. Low electron injection efficiency may require a high bias voltage for light generation. Accordingly, it is an object of the present invention, which has been accomplished in light of the circumstances described above, to provide a nitrite semiconductor light-emitting device, provided on a semipolar surface, to reduce an increase in bias voltage applied to emit light, and to provide a method of fabricating the nitrite semiconductor light-emitting device.

An InGaN quantum well structure formed on the c-plane of the hexagonal nitride semiconductor has a barrier layer with a thickness within the range of, for example, 5 to 20 nm. In particular, the light-emitting device that emits light of a relatively long wavelength preferably has a relatively thick barrier layer in thickness due to a relatively large indium composition of the well layer, because the crystal quality of the well layer is made low because of its relatively large indium composition, and the crystal quality is recovered as the barrier layer grows, so that the crystal surface of the barrier layer becomes improved. In fabricating a light-emitting device having a quantum well structure on a semipolar surface in consideration of such circumstances, the inventors have fabricated a light-emitting layer of a multiple quantum well structure including a barrier layer with a thickness of approximately 15 nm, in such a manner similar to fabrication of a light-emitting device of a quantum well structure on the c-plane. Unfortunately, a light-emitting device having a quantum well structure on the semipolar surface requires a relatively higher bias voltage for light generation.

Thus, in the application of a bias voltage in measurement of photoluminescence (PL) in order to find the cause for the relatively high voltage required for light generation, the inventors have studied the optical properties of the crystal orientation of an InGaN quantum well structure. The inventors' studies have discovered that the direction of the piezoelectric polarization of the well layer in the InGaN quantum well structure on a semipolar surface is opposite to the direction of the piezoelectric polarization of the well layer in the InGaN quantum well structure on the c-plane. The inventors have also discovered that the opposite direction of the piezoelectric polarization reduces the efficiency of electron injection to the InGaN quantum well structure, thus, raising the bias voltage required for light generation. Such a low electron injection efficiency in the InGaN quantum well structure has not been commonly recognized because of the following reasons: The direction of piezoelectric polarization in an InGaN quantum well layer of an InGaN quantum well structure on the c-plane is different from the direction in which electron injection in the InGaN quantum well structure is reduced; and piezoelectric polarization have a relatively small effect on the injection efficiency of holes because the valence band has a small band offset.

Meanwhile, the inventors have discovered the structure and the InGaN crystal property therefor that allow the growth of a well layer having a relatively large indium composition with acceptable crystal quality when fabricating a multiple quantum well structure on a semipolar surface of a certain tilt angle, which can advantageously provide a high indium incorporation and a high crystal quality due to growth mode. The inventors have discovered that the properties of the InGaN crystal and the use of a semipolar surface enables the growth of a quantum well structure with relatively high crystal quality and high luminance efficiency when using a thin barrier layer in thickness, which has a low luminance efficiency due to insufficient recovery of crystallinity if grown on the c-plane, The inventors have studied the relationship between the barrier layer thickness of the InGaN multiple quantum well structure on a semipolar surface and the crystal quality of this quantum well structure. As a result, the inventors have found out the structure on a semipolar surface that includes a barrier layer with a relatively small thickness which is the same order as that of the well layer and that can provide an excellent crystal quality without reduction in the PL luminescence intensity reflecting its crystallinity. The inventors have fabricated a light-emitting device of an InGaN quantum well structure, including a barrier layer of a relatively thin thickness which is the same order as that of the well layer, on a semipolar surface. The fabricated light-emitting device have had advantages such as reduction in a bias voltage for light generation, a small full-width half-maximum of the emission wavelength, and high luminance efficiency, leading to an increase in the carrier injection efficiency.

A number of aspects of the present invention have been accomplished on the basis of knowledge, which the inventors have acquired, regarding an InGaN multiple quantum well structure provided on a semipolar plane. These aspects will be described below.

A first aspect of the present invention relates to a nitride semiconductor light-emitting device. The nitride semiconductor light-emitting device includes: (a) a support base comprising a hexagonal nitride semiconductor and having a primary surface tilting in a predetermined direction from a c-plane of the hexagonal nitride semiconductor; (b) an n-type gallium nitride-based semiconductor layer disposed over the primary surface of the support base; (c) a light-emitting layer comprising a gallium nitride-based semiconductor disposed over the n-type gallium nitride-based semiconductor layer; and (d) a p-type gallium nitride-based semiconductor layer disposed over the light-emitting layer. The light-emitting layer has a multiple quantum well structure; the multiple quantum well structure comprises at least two well layers and at least one barrier layer; the barrier layer is disposed between the two well layers; the two well layers comprise InGaN; the two well layers have a first indium composition within the range of 0.15 to 0.50; the tilt angle defined by the c-plane and the primary surface is within the range of 50 to 80 degrees or 130 to 170 degrees; and the barrier layer has a thickness within the range of 1.0 to 4.5 nm.

The primary surface of the support base of the nitride semiconductor light-emitting device according to the first aspect of the present invention comprises a semipolar surface tilted at an angle in the range of 50 to 80 degrees or 130 to 170 degrees. The nitride semiconductor light-emitting device includes a light-emitting layer having a multiple quantum well structure provided on the primary surface. The direction of the piezoelectric polarization in the well layers, which is provided on a semipolar surface and has a multiple quantum well structure, is opposite to the direction of the piezoelectric polarization in the well layers provided on the c-plane. Thus, the band structure of the multiple quantum well structure provided on a semipolar surface is strained in a different way as the strain on the c-plane. The strain in the band structure causes low electron injection efficiency in the light-emitting layer. The thickness of the barrier layer of the nitride semiconductor light-emitting device is relatively small within the range of 1.0 to 4.5 nm. Thus, electrons readily pass over the energy barrier of the barrier layer, improving the electron injection efficiency in the light-emitting layer, regardless of strain in the band structure.

The two well layers of the nitride semiconductor light-emitting device according to the first aspect of the present invention have a relatively large first indium composition within the range of 0.15 to 0.50. It is preferable that a relatively thick barrier layer in thickness be used for a well layer having such a relatively large indium composition in order to prevent the crystallinity of the barrier layer from becoming degraded in the growth of the light emitting layer. The light-emitting layer (multiple quantum well structure) of the nitride semiconductor light-emitting device according to the first aspect of the present invention is disposed on the semipolar surface at an angle that achieves excellent indium incorporation and an excellent growth mode for InGaN growth. Thus, the crystallinity of a barrier layer with a relatively small thickness within the range of 1.0 to 4.5 nm can be improved, maintaining the crystal quality of the light-emitting layer. The crystallinity is insufficiently improved in a barrier layer having a thickness less than 1.0 nm, impairing the crystallinity of the light-emitting layer.

In the first aspect of the present invention, the thickness of the barrier layer is preferably smaller than or equal to the sum of the thickness of one of the well layers and 0.50 nm and preferably larger than or equal to the difference between the thickness of one of the well layers and 0.50 nm. The thickness of the barrier layer is substantially equal to the thickness of the well layers. Thus, electrons can readily pass over the energy barrier of the barrier layer into adjoining well layers regardless of strain, caused by piezoelectric polarization in a direction opposite to that on the c-plane, in the band structure of the light-emitting layer. This effectively prevents reduction of the electron injection efficiency in the light-emitting layer.

In the first aspect of the present invention, the barrier layer preferably comprises InGaN, and the barrier layer preferably has a second indium composition within a range of 0.01 to 0.10. The second indium composition within the range of 0.01 to 0.10 provides the barrier layer with the small band gap. Thus, electrons can readily pass over the energy barrier of the barrier layer, regardless of strain in the band structure of the light-emitting layer due to piezoelectric polarization in a direction opposite to that on the c-plane. This effectively prevents the decreasing of the electron injection efficiency in the light-emitting layer. A second indium composition of the barrier layer exceeding 0.10 may reduce the crystallinity of the barrier layer and the light-emitting layer.

In the first aspect of the present invention, it is preferable that the n-type gallium nitride-based semiconductor layer have an InGaN layer, the light-emitting layer be disposed over the InGaN layer, misfit dislocations exist on the surface of the InGaN layer on a side of the support base inside the n-type gallium nitride-based semiconductor layer, the misfit dislocations extend in a direction orthogonal to the c-axis and the reference axis that is shared by the surface of the InGaN layer and a reference plane orthogonal to the surface of the InGaN layer and containing the c-axis of the hexagonal nitride semiconductor, and the density of the misfit dislocations be within a range of 5×10³ to 1×10⁵ cm⁻¹. The InGaN layer is disposed between the support base and the light-emitting layer. The surface of the InGaN layer on the support base side has a relatively high density of misfit dislocations. The InGaN layer relaxes the strain on the support base, reducing the strain incorporated in the well layers. Thus, the piezoelectric polarization is reduced, regardless of strain in the band structure of the light-emitting layer formed by the piezoelectric polarization in a direction opposite to that on the c-plane, preventing impairment in the electron injection efficiency in the light-emitting layer. A misfit dislocation density exceeding 1×10⁵ cm⁻¹ may reduce the luminance efficiency in the light-emitting layer due to defects resulting from the misfit dislocations.

In the first aspect of the present invention, the InGaN layer preferably has a third indium composition within a range of 0.03 to 0.05. The InGaN layer, which is provided between the support base and the light-emitting layer and relaxes the strain on the support base, has an indium composition within the range of 0.03 to 0.05, so that the strain on the support base is satisfactorily alleviated. Thus, regardless of strain in the band structure of the light-emitting layer formed by the piezoelectric polarization in a direction opposite to that on the c-plane, impairment of the electron injection efficiency in the light-emitting layer is effectively prevented. The InGaN layer having the third indium composition larger than 0.05 has highly dense misfit dislocations, and these dense misfit dislocations may reduce the luminance efficiency.

In the first aspect of the present invention, the second indium composition preferably increases in the direction from the p-type gallium nitride-based semiconductor layer to the n-type gallium nitride-based semiconductor layer. The indium composition of the barrier layer increases in a direction from the p-type gallium nitride-based semiconductor layer to the n-type gallium nitride-based semiconductor layer. Thus, compared with a barrier layer that has the same indium composition in the direction from the p-type gallium nitride-based semiconductor layer to the n-type gallium nitride-based semiconductor layer, the band gap of the barrier layer decreases on the side of the n-type gallium nitride-based semiconductor layer. Thus, regardless of strain, generated by the piezoelectric polarization in a direction opposite to that on the c-plane, in the band structure of the light-emitting layer, the band gap of the barrier layer can be changed to relax the strain and promote the electrons to pass over the energy barrier of the barrier layer, preventing impairment of the electron injection efficiency in the light-emitting layer.

In the first aspect of the present invention, a tilt angle defined by the c-plane and the primary surface is preferably within a range of 63 to 80 degrees. A tilt angle of the primary surface within the range of 63 to 80 degrees has excellent indium incorporation and an excellent growth mode for InGaN growth, enhancing the crystallinity of a thin barrier layer, and preventing reduction of the luminance efficiency. Accordingly, electron injection efficiency can be improved without impairment of luminance efficiency.

In the first aspect of the present invention, the first indium composition is preferably within a range of 0.24 to 0.40. The indium composition of the well layers within a range of 0.24 to 0.40 causes the light-emitting layer to emit light having a wavelength within the range of 500 to 570 nm. The band offset between the well layers and the barrier layer is relatively large when the well layers have a relatively large indium composition. Thus, the piezoelectric polarization has a significant influence on the strain of the band structure. In such a case, also, the electron injection efficiency can be satisfactorily made reduced in the light-emitting layer.

In the first aspect of the present invention, the second indium composition is preferably within a range of 0.01 to 0.06. The indium composition of the barrier layer within a range of 0.01 to 0.06 satisfactorily prevents the deterioration in the crystallinity.

In the first aspect of the present invention, the thickness of the barrier layer is preferably within a range of 1.0 to 3.5 nm. The thickness of the barrier layer is relatively small within a range of 1.0 to 3.5 nm. Thus, electrons can readily pass over the energy barrier of the barrier layer into adjoining well layers, regardless of strain in the band structure. This effectively prevents reduction of the electron injection efficiency in the light-emitting layer.

A second aspect of the present invention relates to a method of fabricating a nitride semiconductor light-emitting device. The method includes the steps of: (a) preparing a substrate which comprises a hexagonal nitride semiconductor and has a primary surface tilting in a predetermined direction from a c-plane of the hexagonal nitride semiconductor; (b) growing an n-type gallium nitride-based semiconductor layer over the primary surface of the substrate; (c) growing a light-emitting layer which comprises a gallium nitride-based semiconductor over the n-type gallium nitride-based semiconductor layer; and (d) growing a p-type gallium nitride-based semiconductor layer over the light-emitting layer. The light-emitting layer includes at least a first well layers, a second well layer, and a barrier layer; in the step of growing the light-emitting layer, the first well layer, the barrier layer, and the second well layer are grown, in sequence, over the n-type gallium nitride-based semiconductor layer; the first well layer and the second well layer comprise InGaN; the first well layer and the second well layer have a first indium composition within a range of 0.15 to 0.50; the tilt angle defined by the c-plane and the primary surface is within a range of 50 to 80 degrees or 130 to 170 degrees; and the barrier layer has a thickness within a range of 1.0 to 4.5 nm.

The primary surface of the support base of the nitride semiconductor light-emitting device according to the second aspect of the present invention comprises a semipolar surface within the range of 50 to 80 degrees or 130 to 170 degrees. The nitride semiconductor light-emitting device according to the second aspect of the present invention includes a light-emitting layer having a multiple quantum well structure disposed over the primary surface. The direction of the piezoelectric polarization in the well layers, which are provided on a semipolar surface and constitutes a multiple quantum well structure, is opposite to the direction of the piezoelectric polarization in a well layer disposed over a c-plane. Thus, the band structure of the multiple quantum well structure provided on the semipolar surface is strained in a different way as that on the c-plane. The strain in the band structure causes low electron injection efficiency in the light-emitting layer. The thickness of the barrier layer of the nitride semiconductor light-emitting device according to the second aspect of the present invention is relatively small within the range of 1.0 to 4.5 nm. Thus, electrons readily pass over the energy barrier of the barrier layer into the adjoining well layers regardless of strain in the band structure, enhancing the electron injection efficiency in the light-emitting layer.

The two well layers of the nitride semiconductor light-emitting device according to the second aspect of the present invention have a relatively large first indium composition within the range of 0.15 to 0.50. A barrier layer having a relatively large thickness is preferably used for well layers of such a relatively large indium composition so as to maintain high crystallinity of the barrier layer. The light-emitting layer (multiple quantum well structure) of the nitride semiconductor light-emitting device according to the second aspect of the present invention is disposed on the semipolar surface at an angle that achieves excellent indium incorporation and a preferable growth mode for InGaN growth. Thus, a barrier layer with a relatively small thickness in the range of 1.0 to 4.5 nm can make its crystallinity enhanced, maintaining the crystal quality of the light-emitting layer. The crystallinity is insufficiently enhanced in a barrier layer having a thickness less than 1.0 nm, impairing the crystallinity of the light-emitting layer.

In the second aspect of the present invention, the thickness of the barrier layers is preferably smaller than or equal to the sum of the thickness of one of the well layers and 0.5 nm and preferably larger than or equal to the difference between the thickness of one of the well layers and 0.5 nm. The thickness of the barrier layer is substantially equal to the thickness of the well layers. Thus, regardless of strain in the band structure of the light-emitting layer due to piezoelectric polarization in a direction opposite to that on the c-plane, electrons can readily pass over the energy barrier of the barrier layer into adjoining barrier layers. This effectively prevents impairment of the electron injection efficiency in the light-emitting layer.

In the second aspect of the present invention, the barrier layer preferably comprises InGaN, and the barrier layer preferably has a second indium composition within a range of 0.01 to 0.10. Since the second indium composition of the barrier layer within the range of 0.01 to 0.10 reduces the band gap of the barrier layer, electrons readily pass over the energy barrier of the barrier layer regardless of strain in the band structure of the light-emitting layer generated by the piezoelectric polarization in the direction opposite to that on the c-plane, preventing impairment of the electron injection efficiency in the light-emitting layer. A second indium composition of the barrier layer exceeding 0.10 may impair the crystallinity of the barrier layer and light-emitting layer.

In the second aspect of the present invention, it is preferable that the n-type gallium nitride-based semiconductor layer have an InGaN layer, the light-emitting layer be disposed over the InGaN layer, misfit dislocations exist on the surface of the InGaN layer on a side of the substrate inside the n-type gallium nitride-based semiconductor layer, the misfit dislocations extend in a direction orthogonal to the c-axis and the reference axis that is shared by the surface of the InGaN layer and a reference plane orthogonal to the surface of the InGaN layer and containing the c-axis of the hexagonal nitride semiconductor, and the density of the misfit dislocations be within a range of 5×10³ to 1×10⁵ cm⁻¹. The InGaN layer is provided between the substrate and the light-emitting layer. The surface of the InGaN layer on the substrate side has a relatively high density of misfit dislocations. The InGaN layer relaxes the strain on the substrate, reducing the inner strain of the well layers. Thus, the piezoelectric polarization is alleviated, regardless of strain in the band structure of the light-emitting layer generated by the piezoelectric polarization in a direction opposite to that on the c-plane, preventing impairment of the electron injection efficiency in the light-emitting layer. A misfit dislocation density exceeding 1×10⁵ cm⁻¹ may reduce the luminance efficiency in the light-emitting layer due to defects resulting from the misfit dislocations.

In the second aspect of the present invention, the InGaN layer preferably has a third indium composition within a range of 0.03 to 0.05. The InGaN layer, which is disposed between the substrate and the light-emitting layer and relaxes the strain on the substrate, has an indium composition within the range of 0.03 to 0.05. Thus, the strain on the substrate is satisfactorily reduced, so that the reduction in the electron injection efficiency is prevented in the light-emitting layer even when strain resulting from the piezoelectric polarization is incorporated therein in a direction opposite to that on the c-plane. The InGaN layer having the third indium composition larger than 0.05 has highly dense misfit dislocations, which may impairs the luminance efficiency.

In the second aspect of the present invention, the second indium composition preferably increases from the p-type gallium nitride-based semiconductor layer to the n-type gallium nitride-based semiconductor layer. The indium composition of the barrier layer increases from the p-type gallium nitride-based semiconductor layer to the n-type gallium nitride-based semiconductor layer. Thus, compared with a barrier layer that has the same indium composition in the direction from the p-type gallium nitride-based semiconductor layer to the n-type gallium nitride-based semiconductor layer, the band gap of the barrier layer decreases on the side of the n-type gallium nitride-based semiconductor layer. Thus, regardless of strain in the band structure of the light-emitting layer generated by the piezoelectric polarization in a direction opposite to that on the c-plane, the band gap of the barrier layer can be changed to relax the strain and promote the electrons to pass over of the energy barrier of the barrier layer, preventing impairment of the electron injection efficiency in the light-emitting layer.

In the second aspect of the present invention, a tilt angle defined by the c-plane and the primary surface is preferably within a range of 63 to 80 degrees. A tilt angle of the primary surface within the range of 63 to 80 degrees has excellent indium incorporation and an excellent growth mode for InGaN growth, enhancing the crystallinity of a thin barrier layer, and preventing reduction in the luminance efficiency. Accordingly, electron injection efficiency can be improved without impairment of luminance efficiency.

In the second aspect of the present invention, the first indium composition is preferably within a range of 0.24 to 0.40. The first indium composition of the well layers within a range of 0.24 to 0.40 causes the light-emitting layer to emit light having a wavelength within the range of 500 to 570 nm. The band offset between the barrier layer and the well layers is relatively large when the well layers have a relatively large indium composition. Thus, the piezoelectric polarization has a significant influence on the strain of the band structure. In such a case, also, impairment of the electron injection efficiency in the light-emitting layer can be satisfactorily prevented.

In the second aspect of the present invention, the second indium composition is preferably within a range of 0.01 to 0.06. The second indium composition of the barrier layer within a range of 0.01 to 0.06 satisfactorily prevents impairment in the crystallinity.

In the second aspect of the present invention, the thickness of the barrier layer is preferably within a range of 1.0 to 3.5 nm. The thickness of the barrier layer is relatively small within a range of 1.0 to 3.5 nm. Thus, electrons can readily pass over the energy barrier of the barrier layer into adjoining a well layer, although the band structure is strained. This effectively prevents impairment of the electron injection efficiency in the light-emitting layer.

The above-described object and other objects, features, and advantages of the present invention will be apparent from the detailed description of the embodiments of the present invention with reference to the accompanying drawings.

### BRIEF DESCRIPTION OF THE DRAWINGS

FIG. 1 is a view which illustrates the configuration of a light-emitting device according to an embodiment.

FIG. 2 is a view which illustrates the advantageous effects of a light-emitting device according to an embodiment.

FIG. 3 is a view which illustrates a method of fabricating a light-emitting device according to an embodiment.

FIG. 4 is a schematic view showing a product of primary steps of a method of fabricating a light-emitting device according to an embodiment.

FIG. 5 is a view which illustrates the configuration of a light-emitting device according to an experimental example of an embodiment.

FIG. 6 is a view which illustrates the observed results of PL emission wavelengths in experimental examples.

FIG. 7 is a view which illustrates the observed results of the dependency of emission wavelength on current density in the experimental examples.

FIG. 8 is a view which illustrates the observed results of the dependency of output power on current density in the experimental examples.

FIG. 9 is a view which illustrates the observed results of the dependency of full-width half-maximum of emission wavelengths on current density in the experimental examples.

FIG. 10 is a view which illustrates the observed results of IV characteristics in the experimental examples.

FIG. 11 is a view which illustrates the observed results of IV characteristics in the experimental examples.

FIG. 12 is a view which illustrates the observed results of IV characteristics in the experimental examples.

FIG. 13 is a view which illustrates the observed results of IV characteristics in the experimental examples.

### EMBODIMENTS

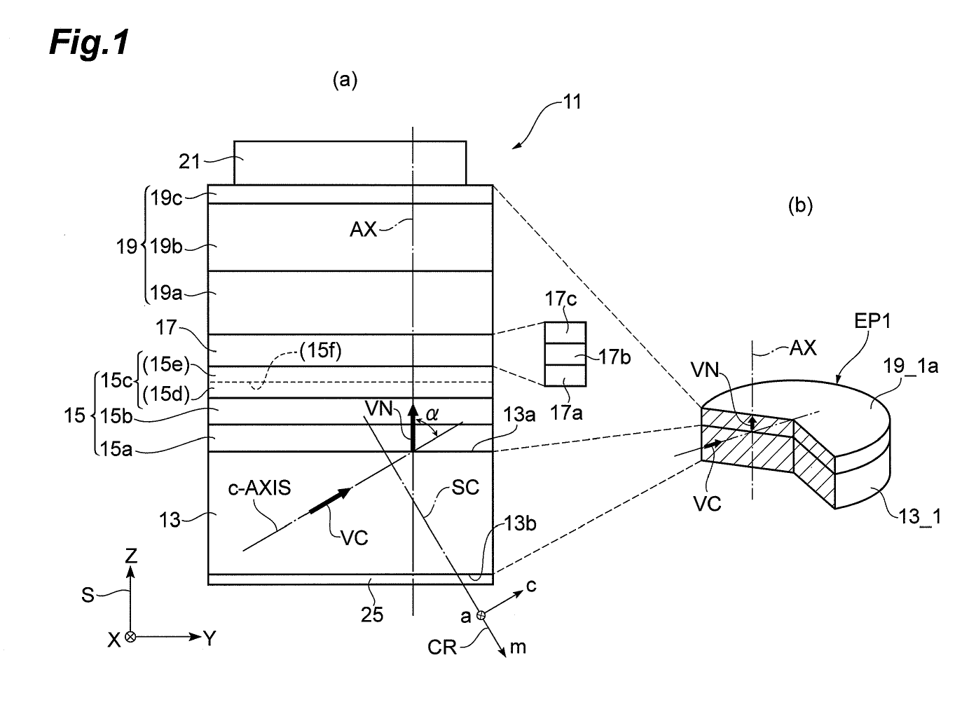

Embodiments of the present invention will now be described in detail with reference to the accompanying drawings. The same elements will be designated by the same references, when appropriate, and the duplicate description thereof may be omitted. FIG. 1 is a schematic view of the structure of a light-emitting device 11, which is a nitride semiconductor light-emitting device according to this embodiment, and the structure of an epitaxial substrate for the light-emitting device 11. The light-emitting device 11 in FIG. 1 is illustrated as a light-emitting diode (LED) for evaluating spontaneous emission from an epitaxial structure for a laser diode (LD) (an epitaxial structure applicable to an LD) but may be an LD.

Part (a) of FIG. 1 illustrates the light-emitting device 11, and Part (b) of FIG. 1 illustrates an epitaxial substrate EP1 of the light-emitting device 11. The epitaxial substrate EP1 has an epitaxial layer structure (a support base 13, an n-type gallium nitride-based semiconductor layer 15, a light-emitting layer 17, and a p-type gallium nitride-based semiconductor layer 19) that is similar to that of the light-emitting device 11. The semiconductor layers constituting the light-emitting device 11 will be described below. The epitaxial substrate EP1 includes semiconductor layers (semiconductor films) corresponding to semiconductor layers constituting the light-emitting device 11, and the description for the semiconductor layers of the light-emitting device 11 is applicable thereto.

FIG. 1 illustrates an orthogonal coordinate system S and a crystal coordinate system CR. The crystal coordinate system CR defines crystal axes (c-axis, a-axis, and m-axis) of a hexagonal nitride semiconductor of the support base 13. The X-axis is parallel to the a-axis of the hexagonal nitride semiconductor of the support base 13, and the YZ-plane is parallel to a plane defined by the m- and c-axes of the hexagonal nitride semiconductor of the support base 13.

As illustrated in Part (a) of FIG. 1, the light-emitting device 11 includes a support base 13, an n-type gallium nitride-based semiconductor layer 15, a light-emitting layer 17, a p-type gallium nitride-based semiconductor layer 19, a p-side electrode 21, an insulating layer 23, and an n-side electrode 25. The n-type gallium nitride-based semiconductor layer 15 includes an n-type GaN layer 15a, an n-type cladding layer 15b, and an n-type guiding layer 15c. The light-emitting layer 17 has a multiple quantum well structure including a well layer 17a, a barrier layer 17b, and a well layer 17c. The light-emitting layer 17 may have a multiple quantum well structure including three or more well layers. The p-type gallium nitride-based semiconductor layer 19 includes a p-type guiding layer 19a, a p-type cladding layer 19b, and a p-type contact layer 19c. The n-type gallium nitride-based semiconductor layer 15, the light-emitting layer 17, and the p-type gallium nitride-based semiconductor layer 19 are epitaxially grown over the support base 13. The n-type GaN layer 15a, the n-type cladding layer 15b, the n-type guiding layer 15c, the well layer 17a, the barrier layer 17b, the well layer 17c, the p-type guiding layer 19a, the p-type cladding layer 19b, and the p-type contact layer 19c are arranged, in sequence, on the primary surface 13a of the support base 13.

The c-plane of the support base 13 extends along a plane SC. The primary surface 13a of the support base 13 intersects with the Z-axis and extends parallel to the XY-plane. The primary surface 13a tilts away from the c-plane in a predetermined direction. The tilt angle α of the primary surface 13a is defined with respect to the c-plane of the hexagonal nitride semiconductor of the support base 13 (the (0001) plane and the plane SC illustrated in FIG. 1). The primary surface 13a may tilt at a tilt angle α with respect to the plane SC for the c-plane toward, for example, the m-axis of the support base 13. The tilt angle α is defined by a normal vector VN of the primary surface 13a of the support base 13 and the c-axis vector VC indicating the c-axis. The tilt angle α is in the range of 50 to 80 degrees or 130 to 170 degrees. The tilt angle α may specifically be within the range of 63 to 80 degrees. The primary surface 13a tilts, for example, from the c-plane toward the m-axis. In particular, if the tilt angle α is 75 degrees from the c-plane toward the m-axis, this primary surface 13a corresponds to the (20-21) plane of the hexagonal nitride semiconductor of the support base 13. The c-axis vector VC corresponds to the normal vector of the (0001) plane.

On the primary surface 13a, the light-emitting layer 17 is provided between the n-type gallium nitride-based semiconductor layer 15 and the p-type gallium nitride-based semiconductor layer 19. The n-type gallium nitride-based semiconductor layer 15, the light-emitting layer 17, and the p-type gallium nitride-based semiconductor layer 19 are arrayed in sequence on the primary surface 13a along the normal vector VN (Z-axis). The n-type GaN layer 15a, the n-type cladding layer 15b, and the n-type guiding layer 15c of the n-type gallium nitride-based semiconductor layer 15 are arrayed in sequence on the primary surface 13a along the normal vector VN (Z-axis). The well layer 17a, the barrier layer 17b, and the well layer 17c of the light-emitting layer 17 are arrayed in sequence on the primary surface 13a along the normal vector VN (Z-axis). The p-type guiding layer 19a, the p-type cladding layer 19b, and the p-type contact layer 19c of the p-type gallium nitride-based semiconductor layer 19 are arrayed in sequence on the primary surface 13a along the normal vector VN (Z-axis).

The support base 13 is composed of, for example, GaN. GaN is a binary compound of gallium nitride-based semiconductor, and thus has excellent crystal quality and provides a stable primary surface with a substrate. Instead of GaN, the support base 13 may be composed of a hexagonal nitride semiconductor, such as InGaN or AlGaN.

The n-type gallium nitride-based semiconductor layer 15 is composed of an n-type gallium nitride-based semiconductor. The n-type dopant of the n-type gallium nitride-based semiconductor layer 15 is, for example, silicon (Si). The n-type gallium nitride-based semiconductor layer 15 is provided on the support base 13. The n-type GaN layer 15a of the n-type gallium nitride-based semiconductor layer 15 is in contact with the primary surface 13a of the support base 13. The n-type GaN layer 15a is composed of n-type GaN. The n-type cladding layer 15b is in contact with the n-type GaN layer 15a. The n-type cladding layer 15b is composed of, for example, an n-type nitride-based semiconductor, such as n-type InAlGaN. The n-type guiding layer 15c is in contact with the n-type cladding layer 15b. The n-type guiding layer 15c may be composed of an n-type gallium nitride-based semiconductor, such as n-type GaN or n-type InGaN.

The n-type guiding layer 15c may include two layers. One of these layers is provided for an n-type GaN guiding layer 15d composed of n-type GaN, and the other layer is provided for an n-type InGaN guiding sub-layer 15e composed of n-type InGaN. The n-type GaN guiding layer 15d is in contact with the n-type cladding layer 15b. The n-type InGaN guiding layer 15e is provided on the n-type GaN guiding layer 15d and is in contact with the n-type GaN guiding layer 15d. The n-type guiding layer 15c has misfit dislocations at the nearer interface 15f (the interface between the n-type GaN guiding layer 15d and the n-type InGaN guiding layer 15e) of the n-type InGaN guiding layer 15e, and the nearer interface 15f is situated nearer the support base in relation to the n-type InGaN guiding layer 15e. Such misfit dislocations extend in a direction (along the a-axis) orthogonal to both the c-axis and a reference axis defined as a line of intersection of the surface 15f with the reference plane, containing the c-axis (a plane parallel to the a-plane), which is orthogonal to the surface 15f of the n-type InGaN guiding layer 15e. The density of the misfit dislocations is within the range of 5×10³ to 1×10⁵ cm⁻¹. The indium composition of the n-type InGaN guiding layer 15e (third indium composition) is in the range of 0.03 to 0.05.

The light-emitting layer 17 has a multiple quantum well structure. The light-emitting layer 17 contains indium and may be composed of a gallium nitride-based semiconductor, such as InGaN.

The well layer 17a is in contact with the n-type InGaN guiding layer 15e of the n-type guiding layer 15c. The well layer 17a contains indium and may be composed of a gallium nitride-based semiconductor, such as InGaN. The barrier layer 17b is in contact with the well layer 17a. The barrier layer 17b is provided between the well layer 17a and the well layer 17c. The barrier layer 17b contains indium and may be composed of a gallium nitride-based semiconductor, such as InGaN. The well layer 17c is in contact with the barrier layer 17b. The well layer 17c contains indium and may be composed of a gallium nitride-based semiconductor, such as InGaN. The band gaps of the well layer 17a and well layer 17c are smaller than the band gap of the barrier layer 17b. The light-emitting layer 17 may include three or more well layers and two or more barrier layers.

The indium composition of the well layer 17a (first indium composition) is within the range of 0.15 to 0.50. The indium composition of the well layer 17a is, for example, approximately 0.30 but may otherwise be approximately 0.25 or approximately 0.35. The well layer 17a has a thickness of, for example, approximately 2.5 nm.

The indium composition of the barrier layer 17b (second indium composition) is within the range of 0.01 to 0.10 but may otherwise be within the range of 0.01 to 0.06. The barrier layer 17b may have a thickness that is smaller than or equal to the sum of the thickness of the well layer 17a or well layer 17c and 0.5 nm and that is larger than or equal to a difference between the thickness of the well layer 17a or well layer 17c and 0.5 nm. The barrier layer 17b has a thickness that is 4.5 nm or less but may otherwise be 4.0 nm or less, 3.5 nm or less, or 3.0 nm or less. For example, the barrier layer 17b may have a thickness in the range of 1.0 to 3.5 nm. The barrier layer 17b has a thickness of 1.0 nm or more. The barrier layer 17b may have an indium composition that increases in the direction from the p-type gallium nitride-based semiconductor layer 19 to the n-type gallium nitride-based semiconductor layer 15.

The indium composition of the well layer 17c (first indium composition) is within the range of 0.15 to 0.50. The indium composition of the well layer 17c is, for example, approximately 0.30 but may otherwise be approximately 0.25 or approximately 0.35. The well layer 17c has a thickness of, for example, approximately 2.5 nm. The well layer 17c has a thickness within the range of, for example, 1 to 5 nm.

An indium composition of the well layers (the well layer 17a and the well layer 17c) of the light-emitting layer 17 within the range of 0.15 to 0.50 leads to an emission wavelength of the light-emitting layer 17 within the range of 480 to 600 nm. The emission wavelength the light-emitting layer 17 may otherwise be in the range of 500 to 570 nm. When the wavelength of the light emitted from the light-emitting layer 17 is in the range of 500 to 570 nm, the indium composition of the well layers (the well layer 17a and the well layer 17c) of the light-emitting layer 17 is in the range of 0.24 to 0.40.

The p-type gallium nitride-based semiconductor layer 19 is composed of a p-type gallium nitride-based semiconductor. The p-type dopant in the p-type gallium nitride-based semiconductor layer 19 is, for example, magnesium (Mg). The p-type gallium nitride-based semiconductor layer 19 is in contact with the well layer 17c of the light-emitting layer 17. The p-type guiding layer 19a is provided over the light-emitting layer 17 and is in contact with the light-emitting layer 17. The p-type guiding layer 19a contains at least one p-type gallium nitride-based semiconductor layer. The p-type guiding layer 19a includes an undoped (ud) InGaN layer. The undoped InGaN layer is in contact with the well layer 17c. The p-type guiding layer 19a includes a p-type InGaN layer provided over the undoped InGaN layer. The p-type InGaN layer is in contact with the undoped InGaN layer. The p-type guiding layer 19a includes a p-type GaN layer provided over the p-type InGaN layer. The p-type GaN layer is in contact with the p-type InGaN layer.

The p-type cladding layer 19b is composed of, for example, p-type InAlGaN. The p-type cladding layer 19b is provided over a p-type GaN layer which the p-type guiding layer 19a contains, and is in contact with this p-type GaN layer.

The p-type contact layer 19c is provided over the p-type cladding layer 19b and is in contact with the p-type cladding layer 19b. The p-type contact layer 19c is composed of, for example, p-type GaN.

In the case where the light-emitting device 11 is an LED, the p-side electrode 21 is provided on the p-type contact layer 19c, as illustrated in FIG. 1. The p-side electrode 21 is composed of, for example, palladium (Pd). The n-side electrode 25 is provided on the back surface 13b of the support base 13. The n-side electrode 25 covers the back surface 13b. The n-side electrode 25 is in contact with the back side 13b of the support base 13.

In the case where the light-emitting device 11 is an LD, the p-type gallium nitride-based semiconductor layer 19 includes a ridge portion; the p-side electrode 21 may include an electrode composed of Ni/Au and a pad electrode composed of Ti/Au; and the n-side electrode 25 may include an electrode composed of Ti/Al and a pad electrode composed of Ti/Au. A dielectric multilayer is provided on each end face for the optical cavity. The dielectric multilayer is composed of, for example, SiO₂/TiO₂.

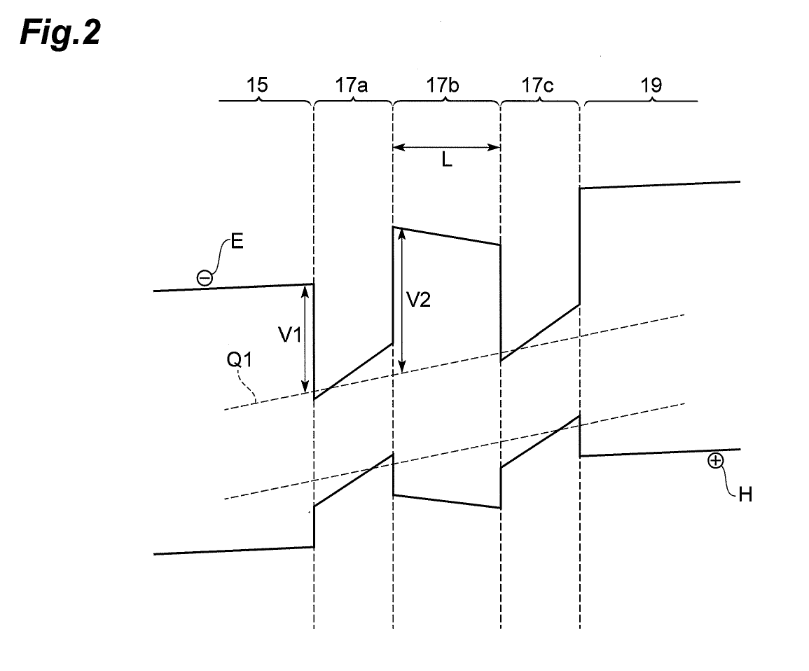

The primary surface 13a of the support base 13 of the light-emitting device 11 having the above-described configuration can be a semipolar surface tilted in the range of 50 to 80 degrees or 130 to 170 degrees. The light-emitting device 11 includes the light-emitting layer 17, which has a multiple quantum well structure, disposed over the primary surface 13a. If the well layer 17a and the well layer 17c were on the c-plane, the direction of the piezoelectric polarization in the light-emitting layer 17, which has a multiple quantum well structure on the semipolar surface, could be opposite to the direction of the piezoelectric polarization on the c-plane. Thus, the band structure of the multiple quantum well structure on the semipolar surface is strained in a way different from that on the c-plane. The strain in the band structure causes low electron injection efficiency in the light-emitting layer 17. The direction of the piezoelectric polarization in the light-emitting layer 17 is the same as the direction from the p-region to the n-region in the light-emitting device 11. As seen from the band diagram illustrated in FIG. 2, electrons E in the well layer 17a must overcome a barrier V2 (a barrier value with respect to a quantum level Q1) against the p-type gallium nitride-based semiconductor layer 19 (p-side) and must overcome a barrier V1 (a barrier value in respect to a quantum level Q1) against the n-type gallium nitride-based semiconductor layer 15 (n-side). The barrier V2 of the well layer 17a is higher than the barrier V1 of the well layer 17a due to the piezoelectric polarization associated with strain in the band structure. The barrier V2, which is higher than the barrier V1, prevents electrons E, which have traveled from the n-type gallium nitride-based semiconductor layer 15, from readily passing over the energy barrier of the barrier layer 17b to move from the well layer 17a to the well layer 17c. As a result, the high barrier V2 of the thick barrier layer may impair the injection efficiency in the light-emitting layer 17. The barrier layer 17b of the light-emitting device 11 having a relatively small thickness of 4.5 nm or less, however, can leads to high electron injection efficiency in the light-emitting layer 17, which has a strained band structure as described above, as compared with the light-emitting layer having a quantum well structure of a thick barrier layer. Referring to the band diagram in FIG. 2, since the thickness L of the barrier layer 17b in the range of 1.0 to 4.5 nm is relatively small, electrons E, which have traveled from the n-type gallium nitride-based semiconductor layer 15, can readily move from the well layer 17a to the well layer 17c by passing over the energy barrier of the barrier layer 17b, preventing reduction in the injection efficiency in the light-emitting layer 17. The thickness of the well layers 17a, 17b, and 17c may be within the range of 1 to 5 nm.

The two well layers (the well layer 17a and the well layer 17c) of the light-emitting device 11 have a relatively large indium composition in the range of 0.15 to 0.50. In order to form the well layer 17a and the well layer 17c with such a relatively large indium compositions, it is preferable that the barrier layer 17b with a large thickness should be used so that the crystallinity of the well layers that is made degraded in growth of the light-emitting layer becomes better during growth of the barrier layer 17b. But, when the light-emitting layer 17 of the light-emitting device 11 in this embodiment uses a semipolar surface tilting at an angle that can provide excellent indium incorporation and an excellent growth mode for InGaN growth, the crystallinity of a barrier layer 17b with a thickness of 4.5 nm or less can be made excellent. In this way, using a relatively thin barrier layer in thickness for the light-emitting layer 17 makes the crystal quality recovered.

The light-emitting layer 17 having a barrier layer 17b with a thickness of less than 1.0 nm has low crystallinity because the crystallinity of the barrier layer 17b is insufficiently recovered during its crystal growth. Referring to FIG. 2, in a band structure strained due to piezoelectric polarization, since the band offset is relatively small for holes H, the strain incorporated therein does not have much influence on the injection efficiency.

The thickness L of the barrier layer 17b may be smaller than or equal to a value which the thickness of the well layer 17a or well layer 17c plus 0.50 nm equals, and larger than or equal to a value which the thickness of the well layer 17a or well layer 17c minus 0.50 nm equals. In such a case, the thickness of the barrier layer 17b is substantially equal to the thickness of the well layer 17a or well layer 17c. Thus, although the band structure of the light-emitting layer 17 incorporates the strain due to the piezoelectric polarization in a direction opposite to that on the c-plane, electrons can pass over the energy barrier of the barrier layer 17b of a thickness similar to the well layers to readily move from the well layer 17a to the barrier layer 17b, thereby preventing the electron injection efficiency from decreasing in the light-emitting layer 17. The thickness of each of the well layer 17a, the barrier layer 17b, and the well layer 17c may be in the range of 1 to nm.

When a barrier layer 17b is composed of InGaN, the barrier layer 17b has an indium composition within the range of 0.01 to 0.1. Since the barrier layer 17b having an indium composition within the range of 0.01 to 0.10 forms a low barrier the band gap of the barrier layer 17b can be changed so as to reduce its strain by use of a plane orientation in which strain occurs in the band structure of the light-emitting layer 17 due to the piezoelectric polarization of the direction opposite to that on the c-plane, so that electrons can readily pass over the energy barrier of the barrier layer 17b, which prevent the reduction in the electron injection efficiency in the light-emitting layer 17. An indium composition of the barrier layer 17b larger than 0.10 may impair the crystallinity of the barrier layer 17b and the well layers 17a and 17c.

The n-type InGaN guiding sub-layer 15e may have an indium composition within the range of 0.03 to 0.05. An n-type InGaN guiding layer 15e having an indium composition within the range of 0.03 to 0.05 sufficiently can reduce the strain incorporated in the light-emitting layer 17 when located between the support base 13 and the light-emitting layer 17. Consequently, in the light-emitting layer 17 strained due to the piezoelectric polarization of a direction opposite to that on the c-plane, its band structure can effectively prevent the reduction in the electron injection efficiency of the light-emitting layer 17. An n-type InGaN guiding layer 15e having an indium composition larger than 0.05 may have low luminance efficiency.

The n-type guiding layer 15c of the n-type gallium nitride-based semiconductor layer 15 includes the n-type GaN guiding layer 15d, the n-type InGaN guiding layer 15e, and the front surface (interface) 15f. The n-type GaN guiding layer 15d may be disposed between the support base 13 and the n-type InGaN guiding layer 15e such that the n-type GaN guiding sub-layer 15d and the n-type InGaN guiding layer 15e define the surface (interface) 15f, and the light-emitting layer 17 may be provided over the n-type InGaN guiding layer 15e. Misfit dislocations are formed at the surface 15f of the n-type InGaN guiding layer 15e inside the n-type gallium nitride-based semiconductor layer 15 and the location of misfit dislocations is away from the light-emitting layer 17. The misfit dislocations extend in a direction orthogonal to the c-axis and a reference axis defined by a line of intersection of the surface 15f and the reference plane that contains the c-axis of the hexagonal gallium nitride-based semiconductor of the support base 13 and is orthogonal to the surface 15f of the n-type InGaN guiding layer 15e. The density of the misfit dislocations may be within the range of 5×10³ to 1×10⁵ cm⁻¹. In this embodiment, the n-type InGaN guiding layer 15e is disposed between the support base 13 and the light-emitting layer 17. The n-type InGaN guiding layer 15e has the surface 15f, which is closer to the support base 13, and another face (interface) which is closer to the light-emitting layer 17. The surface 15f has a relatively high density of misfit dislocations. Thus, in the semiconductor layer of the n-type InGaN guiding layer 15e, the strain resulting from the lattice constant of the support base 13 is relaxed by the n-type InGaN guiding layer 15e and the misfit dislocations, thereby alleviating the inner strain in the light-emitting layer 17. Thus, the piezoelectric polarization is alleviated in the light-emitting layer 17 in which strain due to the piezoelectric polarization in a direction opposite to that on the c-plane is generated, and impairment of the electron injection efficiency is prevented in the band structure of the light-emitting layer 17. A misfit dislocation density exceeding 1×10⁵ cm⁻¹ may reduce the luminance efficiency of the light-emitting layer 17 due to defects resulting from the misfit dislocations. When an n-type InGaN guiding layer 15e has an indium composition larger than 0.05, too high misfit dislocations may impair the luminance efficiency.

The indium composition of the barrier layer 17b may increase in the direction from the p-type gallium nitride-based semiconductor layer 19 to the n-type gallium nitride-based semiconductor layer 15. Compared to a barrier layer that has a constant indium composition in the direction from the p-type gallium nitride-based semiconductor layer to the n-type gallium nitride-based semiconductor layer, a low barrier of the band gap in the barrier layer 17b (a barrier at the interface close to the n-type gallium nitride-based semiconductor layer 15), in the light-emitting layer 17 including a region that has an indium composition increasing in the direction of from the p-type gallium nitride-based semiconductor layer 19 to the n-type gallium nitride-based semiconductor layer 15, electrons can readily move from the well layer 17a to the barrier layer 17b. In the band gap structure of the light-emitting layer 17 strained by the piezoelectric polarization of a direction opposite to that on the c-plane, when a graded composition is applied to the barrier layer 17b to form the band gap, electrons can readily pass over the energy barrier of the barrier layer 17b, thereby preventing impairment of the electron injection efficiency in the light-emitting layer 17.

The tilt angle α of the primary surface 13a in respect to the c-plane may be within the range of 63 to 80 degrees. When a tilt angle α of the primary surface 13a is within the range of 63 to 80 degrees, excellent indium incorporation and an excellent growth mode are provided in InGaN growth. Such an angle thus defined allows recovery of the crystallinity during the growth of a thin barrier layer, thereby preventing impairment of the luminance efficiency. Accordingly, excellent electron injection efficiency can be obtained without deterioration of luminance efficiency.

The indium composition of the well layer 17a and the well layer 17c may be within the range of 0.24 to 0.40. Since the well layer 17a and the well layer 17c has an indium composition in the range of 0.24 to 0.40, the light-emitting layer 17 can emit light having a wavelength within the range of 500 to 570 nm. In a light-emitting layer 17 having a relatively large indium composition, since the band offset between the well layers 17a and 17c and the barrier layer 17b is made relatively large, the piezoelectric polarization has a significant influence on the band structure. The above structure can satisfactorily prevent the reduction in the electron injection efficiency in the light-emitting layer 17.

The indium composition of the barrier layer 17b may be within the range of 0.01 to 0.06. The barrier layer 17b having an indium composition within the range of 0.01 to 0.06 satisfactorily prevents impairment in the crystallinity.

The thickness of the barrier layer 17b may be within the range of 1.0 nm to 3.5 nm. Since the barrier layer 17b having a thickness within the range of 1.0 nm to 3.5 nm is relatively thin, electrons can pass over the energy barrier of the barrier layer 17b to readily move from the well layer 17a to the barrier layer 17b by, regardless of strain in the band structure. This satisfactorily prevents impairment of the electron injection efficiency in the light-emitting layer 17.

As illustrated in Part (b) of FIG. 1, the epitaxial substrate EP1 of the light-emitting device 11 includes semiconductor layers (semiconductor films) corresponding to the above-described semiconductor layers of the light-emitting device 11, and the descriptions of the above-described semiconductor layers of the light-emitting device 11 also refer to the semiconductor layers of the epitaxial substrate EP1. The surface roughness of the epitaxial substrate EP1 has the arithmetic average roughness of, for example, 1 nm or less in a 10-μm square.

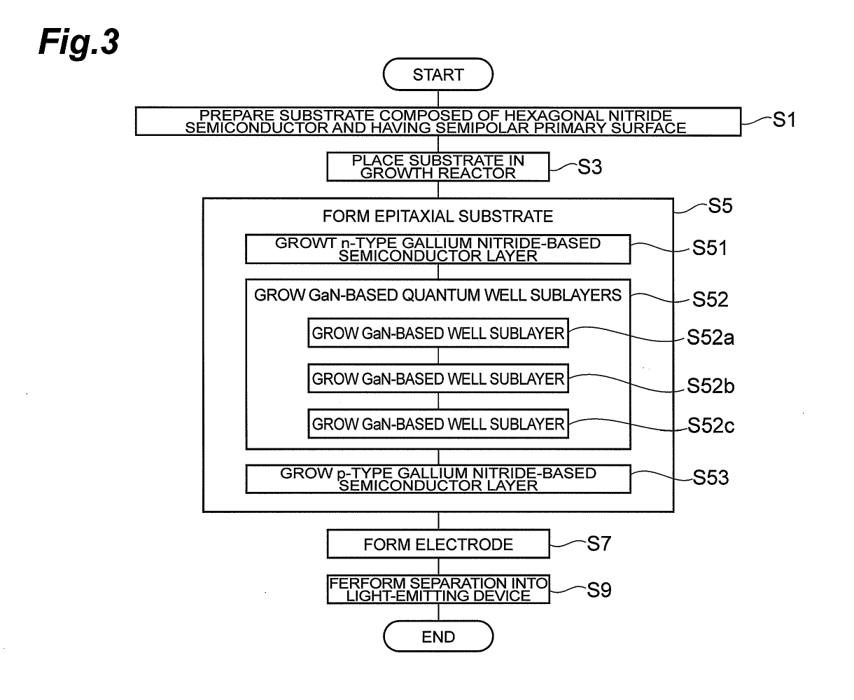

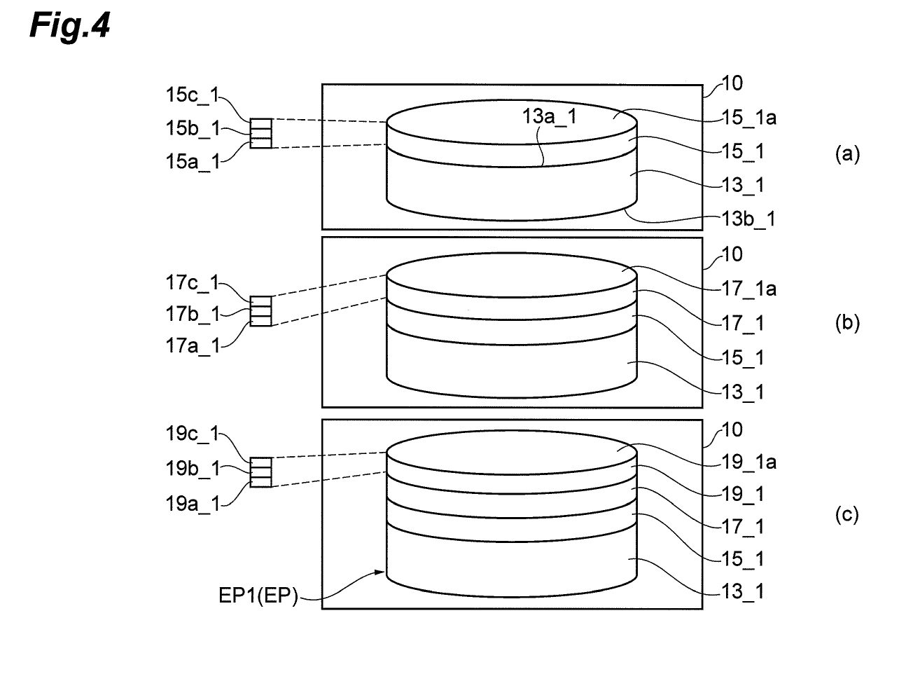

The method of fabricating the light-emitting device 11 according to this embodiment will now be described with reference to FIG. 3 and FIG. 4. FIG. 3 illustrates primary steps in the method of fabricating the light-emitting device 11 according to this embodiment. FIG. 4 is a schematic view of a product obtained through the above steps in the method of fabricating the light-emitting device 11 according to this embodiment. The epitaxial substrate EP in FIG. 4 is a substrate product that corresponds to the epitaxial substrate EP1 illustrated in Part (b) of FIG. 1 and further includes a p-side electrode and an n-side electrode. The epitaxial substrate EP is fabricated from the epitaxial substrate EP1, and then the light-emitting device 11 is separated from the epitaxial substrate EP.

The light-emitting device 11 and the epitaxial substrate EP for fabricating the light-emitting device 11 are fabricated in accordance with a flow chart illustrated in FIG. 3 by metal organic chemical vapor deposition. The following materials are used for epitaxial growth: trimethylgallium (TMG), trimethylindium (TMI), trimethylaluminium (TMA), ammonium (NH₃), silane (SiH₄), and bis(cyclopentadienyl)magnesium (Cp₂Mg).

In Step S1, a substrate 13_1 (corresponding to the support base 13) is prepared, which has a primary surface 13a_1 (corresponding to the primary surface 13a) composed of a gallium nitride-based semiconductor. The substrate 13_1 is illustrated in Part (a) of FIG. 4 and other drawings. The substrate 13_1 has a back surface 13b_1 (corresponding to back face 13b). The back surface 13b_1 is on the side opposite to the primary surface 13a_1. The primary surface 13a_1 is mirror-polished (end of Step S1).

Then, epitaxial growth onto the substrate 13_1 is carried out under the following conditions. In Step S3, the substrate 13_1 is placed in a reactor 10. A quartz tool, such as a quartz flow channel, is provided in the reactor 10. If necessary, the thermal process is carried out for approximately 10 minutes while thermal-processing gas containing NH₃ and H₂ is supplied to the reactor 10 at approximately 1050 degrees Celsius and under a reactor pressure of approximately 27 kPa. Such a thermal process causes modification of the primary surface 13a_1 and other surfaces (end of Step S3).

After the thermal process, in Step S5, a gallium nitride semiconductor layer is grown on the substrate 13_1 to form an epitaxial substrates EP and EP1. The atmosphere gas contains carrier gas and flow gas. The atmosphere gas contains, for example, N₂ and/or H₂.

Step S5 includes the following Steps: S51, S52, and S53. In Step S51, material gas and atmosphere gas are supplied to the reactor 10 to epitaxially grow an n-type gallium nitride-based semiconductor layer 15_1 (corresponding to the n-type gallium nitride-based semiconductor layer 15). The n-type gallium nitride-based semiconductor layer 15_1 is illustrated in Part (a) of FIG. 4 and other drawings. The material gas used in Step S51 contains raw materials for group-III elements and group-V elements, and n-type dopant. An n-type GaN layer 15a_1 (corresponding to the n-type GaN layer 15a) is grown on the primary surface 13a_1. An n-type GaN-based semiconductor layer 15b_1 (corresponding to the n-type cladding layer 15b) is grown on the n-type GaN layer 15a_1. An n-type GaN-based semiconductor layer 15c_1 (corresponding to the n-type guiding layer 15c) is grown on the n-type GaN-based semiconductor layer 15b_1. The tilt angle (corresponding to tilt angle α) of the surface 15_1a of the n-type gallium nitride-based semiconductor layer 15_1 (corresponding to the surface of the n-type GaN-based semiconductor layer 15c_1) corresponds to the tilt angle of the primary surface 13a_1 (end of Step S51). The n-type GaN-based semiconductor layer 15c_1 may be composed of two layers (corresponding to the n-type GaN guiding layer 15d and the n-type InGaN guiding layer 15e). Misfit dislocations exist at the nearer surface of the layer which corresponds to the n-type InGaN guiding layer 15e among the two layers constituting the n-type GaN-based semiconductor layer 15c_1 (the interface between the two layers constituting the n-type GaN-based semiconductor layer 15c_1), and the nearer surface is situated nearer the support base 13_1 in relation to the corresponding layer. The misfit dislocations extend in a direction (along the a-axis) orthogonal to the c-axis and a reference axis that is defined by both an interface and a reference plane, which are defined as follows: the interface is between the two layers constituting the n-type GaN-based semiconductor layer 15c_1; and the reference plane (extending parallel to the a-plane) is orthogonal to the interface between the two layers constituting the n-type GaN-based semiconductor layer 15c_1 and contains the c-axis. The density of the misfit dislocations is within the range of 5×10³ to 1×10⁵ cm⁻¹. The indium composition of the layer corresponding to the n-type InGaN guiding layer 15e, among the two layers constituting the n-type GaN-based semiconductor layer 15c_1, is within the range of 0.03 to 0.05.

In Step S52, the material gas and the atmosphere gas are supplied to the reactor 10 to epitaxially grow a GaN-based quantum well layer 17_1 (corresponding to the light-emitting layer 17). The GaN-based quantum well layer 17_1 is illustrated in Part (b) of FIG. 4 and other drawings. The material gas used in Step S52 contains raw materials for group-III elements and group-V elements. Step S52 includes the following Steps S52a, S52b, and S52c. In Step S52a, a GaN-based well layer 17a_1 (corresponding to the well layer 17a) is grown over the n-type GaN-based semiconductor layer 15c_1. In Step S52b, a GaN-based barrier layer 17b_1 (corresponding to the barrier layer 17b) is grown on the GaN-based well layer 17a_1. In Step S52c, a GaN-based well layer 17_{—}c (corresponding to the well layer 17c) is grown on the GaN-based barrier layer 17b_1 (end of Step S52).

In Step S53, the material gas and the atmosphere gas are supplied to the reactor 10 to epitaxially grow a p-type gallium nitride-based semiconductor layer 19_1 (corresponding to the p-type gallium nitride-based semiconductor layer 19). The p-type gallium nitride-based semiconductor layer 19_1 is illustrated in Part (c) of FIG. 4 and other drawings. The material gas used in Step S53 contains raw materials for group-III elements and group-V elements, and p-type dopants. A p-type GaN-based semiconductor layer 19a_1 (corresponding to the p-type guiding layer 19a) is grown on the GaN-based well layer 17c_1. A p-type GaN-based semiconductor layer 19b_1 (corresponding to the p-type cladding layer 19b) is grown on the p-type GaN-based semiconductor layer 19a_1. A p-type GaN-based semiconductor layer 19c_1 (corresponding to the p-type contact layer 19c) is grown on the p-type GaN-based semiconductor layer 19b_1 (end of Step S53). Steps S51, S52, and S53, which are described above, are carried out to form the epitaxial substrate EP1 and the method ends at Step S5.

In Steps S7 and S9, the n-side electrode and p-side electrode are formed. Steps S7 and S9 for fabricating an LED light-emitting device 11 will now be described. In Step S7, the n-side electrode and the p-side electrode are formed on the epitaxial substrate EP1 to fabricate the epitaxial substrate EP. First, an insulating layer (corresponding to the insulating layer 23) is grown on the front face 19_1a of the p-type gallium nitride-based semiconductor layer 19_1. An opening (corresponding to an opening 23a) is formed in the insulating layer by photolithography and dry etching to expose the surface 19_1a of the p-type GaN-based semiconductor layer 19c_1. The p-side electrode (corresponding to the p-side electrode 21) is grown over the insulating layer by vacuum evaporation. After the back surface 13b_1 of the substrate 13_1 is polished, the n-side electrode (corresponding to the n-side electrode 25) is grown over the back surface 13b_1 by vacuum evaporation. The n-side electrode covers the polished back surface 13b_1. A substrate product is fabricated through the above-described procedures (end of Step S7). Then, in Step S9, the substrate product is separated to fabricate the light-emitting device 11 (Step S9).

Steps S7 and S9 for fabricating an LD light-emitting device 11 will now be described. In Step S7, a ridge portion is formed on the p-type gallium nitride-based semiconductor layer 19_1 by dry etching The ridge portion extends along the c-axis projected on the primary surface of the substrate. A SiO₂ insulating layer (corresponding to the insulating layer 23) is provided over both sides of the ridge portion. The upper face of the ridge portion is exposed through an opening in the insulating layer. The opening extends along the c-axis projected on the primary surface of the substrate. A Ni/Au electrode is grown over the upper surface of the exposed ridge portion by vacuum evaporation. The Ni/Au electrode extends in the direction of the c-axis projected on the primary surface of the substrate. A Ti/Au pad electrode is grown over the insulating layer and the Ni/Au electrode by vacuum evaporation. The Ti/Au pad electrode covers the insulating layer and the Ni/Au electrode. The Ni/Au electrode and the Ti/Au pad electrode constitute a p-side electrode (corresponding to the p-side electrode 21). The back surface 13b_1 of the substrate 13_1 is polished until, for example, the thickness of the epitaxial substrate EP1 becomes approximately 80 μm. A Ti/Al electrode is grown on the polished back face 13b_1 by vacuum evaporation, and a Ti/Au pad electrode is grown on the Ti/Al electrode by vacuum evaporation. The Ti/Al electrode and the Ti/Au pad electrode constitute an n-side electrode (corresponding to the n-side electrode 25). The n-side electrode covers the polished back surface 13b_1 (end of Step S7 for LD fabrication). In Step S9, a laser bar is fabricated from the substrate product. Reflective layers composed of dielectric multilayer (for example, SiO₂/TiO₂) are formed on the end facets of the lasing cavity of the laser bar, and then the separation is carried out to form the light-emitting device 11 (end of Step S9 for LD fabrication).

### EXAMPLES

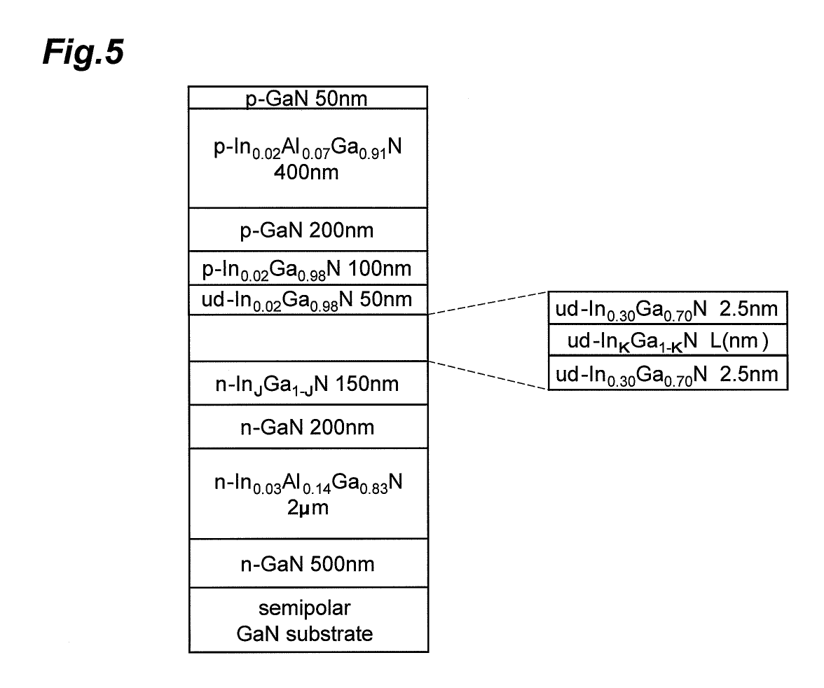

Experimental examples of the light-emitting device 11 according to the embodiments will now be described. FIG. 5 illustrates the configuration of the light-emitting device 11 according to an example. The configuration in FIG. 5 corresponds to the configuration of the epitaxial substrate EP1. A GaN substrate (corresponding to the substrate 13_1 and the support base 13) having a semipolar primary surface (corresponding to the primary surface 13a_1 and the primary surface 13a) is prepared. The primary surface of the GaN substrate extends along a (20-21) plane tilting 75 degrees from the c-plane toward the m-axis of the GaN substrate. The GaN substrate is placed in an NH₃ and H₂ atmosphere at approximately 1050 degrees Celsius for approximately 10 minutes for pre-processing (thermal cleaning).

After thermal cleaning, an n-GaN layer (corresponding to the n-type GaN layer 15a_1 and the n-type GaN layer 15a) is epitaxially grown at approximately 1050 degrees Celsius. Then, the temperature is lowered to approximately 840 degrees Celsius, and an n-In_{0.03}Al_{0.14}Ga_{0.83}N layer having a thickness of approximately 2 μm (corresponding to the n-type GaN-based semiconductor layer 15b_1 and the n-type cladding layer 15b) is epitaxially grown thereon. At approximately 840 degrees Celsius, an n-GaN layer having a thickness of approximately 200 nm (corresponding to the n-type GaN guiding layer 15d) is epitaxially grown thereon. Still at approximately 840 degrees Celsius, an n-InⱼGa_{1-J}N layer having a thickness of approximately 150 nm (corresponding to the n-type InGaN guiding sub-layer 15e) is epitaxially grown thereon.

The temperature is lowered to approximately 790 degrees Celsius, and an In_{0.30}Ga_{0.70}N layer having a thickness of approximately 2.5 nm (corresponding to the GaN-based well layer 17a_1 and the well layer 17a) is epitaxially grown thereon. At a temperature lowered to approximately 840 degrees Celsius, an In_{K}Ga_{1-K}N layer having a thickness L (nm) (corresponding to the GaN-based barrier layer 17b_1 and the barrier layer 17b) is epitaxially grown thereon. At a temperature of approximately 790 degrees Celsius, an In_{0.30}Ga_{0.70}N layer having a thickness of approximately 2.5 nm (corresponding to the GaN-based well layer 17c_1 and the well layer 17c) is epitaxially grown.

The temperature is raised to approximately 840 degrees Celsius, and an undoped In_{0.02}Ga_{0.98}N layer having thickness of approximately 50 nm is epitaxially grown thereon. Then, a p-In_{0.02}Ga_{0.98}N layer having a thickness of approximately 100 nm is epitaxially grown thereon. Then, a p-GaN layer having a thickness of approximately 200 nm is epitaxially grown thereon. A region which is composed of the undoped In_{0.02}Ga_{0.98}N layer having thickness of approximately 50 nm, the p-In_{0.02}Ga_{0.98}N layer having a thickness of approximately 100 nm, and the p-GaN layer having a thickness of approximately 200 nm is associated with the p-type GaN-based semiconductor layer 19a and the p-type guiding layer 19a_1. At approximately 840 degrees Celsius, a p-In_{0.02}Al_{0.07}Ga_{0.91}N layer having a thickness of approximately 400 nm (corresponding to the p-type GaN-based semiconductor layer 19b_1 and the p-type cladding layer 19b) is epitaxially grown thereon. The temperature is raised to approximately 1000 degrees Celsius, and a p-GaN layer having a thickness of approximately 50 nm (corresponding to the p-type GaN-based semiconductor layer 19c_1 and the p-type contact layer 19c) is epitaxially grown thereon.

A light-emitting device 11 (11_1) according to Experimental Example 1 will now be described. In the light-emitting device 11_1, the n-In_{J}Ga_{1-J}N layer corresponding to the n-type InGaN guiding layer 15e has an indium composition J of 0.02; the In_{K}Ga_{1-K}N layer corresponding to the GaN-based barrier layer 17b_1 and the barrier layer 17b has an indium composition K of 0.02; and the In_{K}Ga_{1-K}N layer corresponding to the GaN-based barrier layer 17b_1 and the barrier layer 17b has a thickness L of 2.5 nm. The light-emitting device 11_1 that is configured as described above is referred to as Experimental Example 1.

A light-emitting device 11 (11_2) according to Experimental Example 2 will be described. In the light-emitting device 11_2, the n-In_{J}Ga_{1-J}N layer corresponding to the n-type InGaN guiding layer 15e has an indium composition J of 0.02; the In_{K}Ga_{1-K}N layer corresponding to the GaN-based barrier layer 17b_1 and the barrier layer 17b has an indium composition K of 0.04; and the In_{K}Ga_{1-K}N layer corresponding to the GaN-based barrier layer 17b_1 and the barrier layer 17b has a thickness L of 2.5 nm. The light-emitting device 11_2 that is configured as described above is referred to as Experimental Example 2. Experimental Example 2 is different from Experimental Example 1 in the indium composition K of the In_{K}Ga_{1-K}N layer corresponding to the GaN-based barrier layer 17b_1 and the barrier layer 17b.

A light-emitting device 11 (11_3) according to Experimental Example 3 will be described below. In the light-emitting device 11_3, the n-In_{J}Ga_{1-J}N layer corresponding to the n-type InGaN guiding layer 15e has an indium composition J of 0.02; the In_{K}Ga_{1-K}N layer corresponding to the GaN-based barrier layer 17b_1 and the barrier layer 17b has an indium composition K that continuously varied (increased) from 0.02 to 0.04 in the direction from the p-side to the n-side; and the In_{K}Ga_{1-K}N layer corresponding to the GaN-based barrier layer 17b_1 and the barrier layer 17b has a thickness L of 2.5 nm. The light-emitting device 11_3 that is configured as described above is referred to as Experimental Example 3. There is a difference between Experimental Example 3 and Experimental Example 1 in the indium composition K of the In_{K}Ga_{1-K}N layer corresponding to the GaN-based barrier layer 17b_1 and the barrier layer 17b.

A light-emitting device 11 (11_4) according to Experimental Example 4 will be described. In the light-emitting device 11_4, the n-In_{J}Ga_{1-J}N layer corresponding to the n-type InGaN guiding layer 15e has an indium composition J of 0.04; the In_{K}Ga_{1-K}N layer corresponding to the GaN-based barrier layer 17b_1 and the barrier layer 17b has an indium composition K of 0.02; and the In_{K}Ga_{1-K}N layer corresponding to the GaN-based barrier layer 17b_1 and the barrier layer 17b has a thickness L of 2.5 nm. The light-emitting device 11_4 that is configured as described above is referred to as Experimental Example 4. There is a difference between Experimental Example 4 and Experimental Example 1 in the indium composition J of the n-In_{J}Ga_{1-J}N layer corresponding to the n-type InGaN guiding layer 15e.

Experimental Examples 5 to 7 will be described now. The In_{K}Ga_{1-K}N layer corresponding to the GaN-based barrier layer 17b_1 and the barrier layer 17b in Experimental Example 1 has a thickness L of 0.5 nm. A light-emitting device 11_5 that is configured as described above is referred to as Experimental Example 5. The In_{K}Ga_{1-K}N layer corresponding to the GaN-based barrier layer 17b_1 and the barrier layer 17b in Experimental Example 1 has a thickness L of 5 nm. A light-emitting device 11_6 that is configured as described above is referred to as Experimental Example 6. The In_{K}Ga_{1-K}N layer corresponding to the GaN-based barrier layer 17b_1 and the barrier layer 17b in Experimental Example 1 has a thickness L of 10 nm. A light-emitting device 11_7 that is configured as described above is referred to as Experimental Example 7.

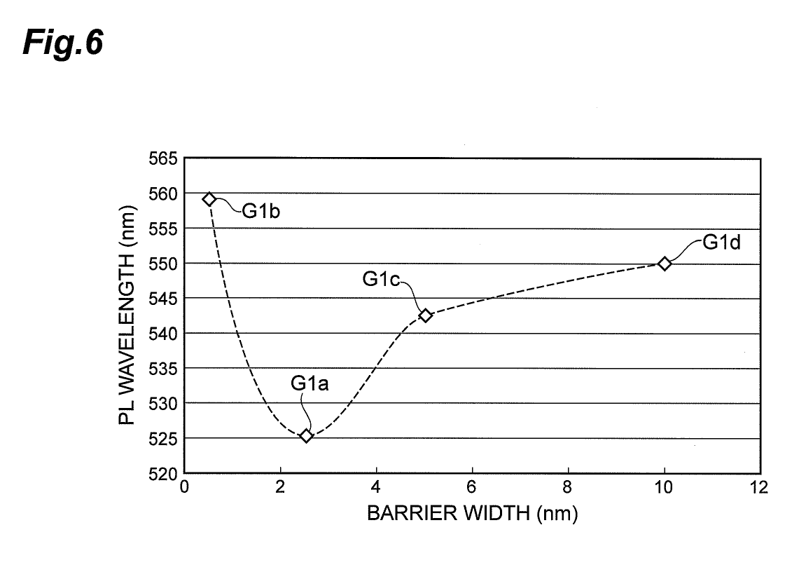

Experimental Example 1 will now be discussed with reference to FIG. 6. FIG. 6 illustrates results of the PL emission wavelength observed in these Experimental Examples. Reference sign G1a represents the result of Experimental Example 1. Reference sign G1b represents the results of Experimental Example 5. Reference sign G1c represents the results of Experimental Example 6. Reference sign G1d represents the results of Experimental Example 7. Referring to FIG. 6, the well layers in Experimental Examples 1, 5, 6, and 7 have the same indium composition. The PL emission wavelength in Experimental Example 1 is significantly shorter than the wavelengths in Experimental Examples 5 to 7. Presumably, this may be a result of the following causes. The piezoelectric polarization of the well layers is negative in a support base having a primary surface corresponding to a semipolar plane, such as a (20-21) plane. Thus, the band structure of the light-emitting layer is strained as illustrated in FIG. 2. As a result, the wave function of the electrons E is shifted to the n-side with of the respect to well layer, and the wave function of the holes is shifted to the p-side with respect to the well layer. As in Experimental Example 1, a relatively thin barrier layer sandwiched between two adjoining well layers causes the above wave functions in two well layers on both side of the barrier layer to overlap each other, and causes the recombination of electrons and holes in the well layers and the recombination of electrons in one of the two well layers and holes in the other of the two well layers to generate light as a result of their recombination, leading to detection of a significantly short PL emission wavelength. A barrier layer having a thickness of 0.5 nm, such as that represented by reference sign G1b in Experimental Example 5, which is much smaller than the thickness 2.5 nm in Experimental Example 1, causes the well layers to work as a well layer having a thickness that is substantially equal to that of a single quantum well structure; thus, the PL emission wavelength is rather long. The PL luminance intensity is measured in these experimental examples. No significant difference in the PL luminance intensity is observed in the results of the measurement of PL luminance intensity for Experimental Examples 1, 6, and 7 in which the thickness of the barrier layer is within the range of 2.5 to 10 nm. However, the PL luminance intensity in Experimental Example 5 in which the thickness of the barrier layer is 0.5 nm is approximately 60% of the PL luminance intensity in Experimental Examples 1, 6, and 7. The results of measurement of the PL luminance intensity in Experimental Example 5 can be explained as follows. The barrier layer formed over the well layer having a large indium composition has a relatively small thickness. A new well layer is grown over the barrier layer before the crystallinity is sufficiently improved, which deteriorates the crystal quality of the overall light-emitting layer, resulting in low PL luminance intensity.

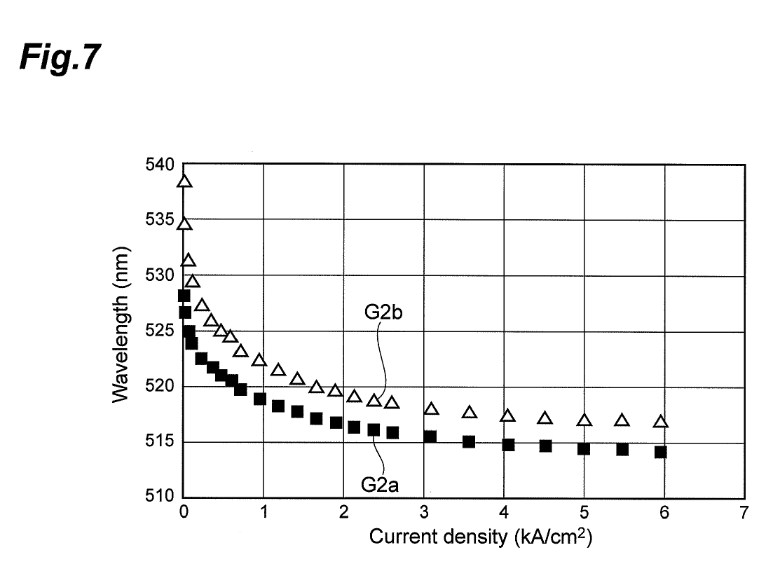

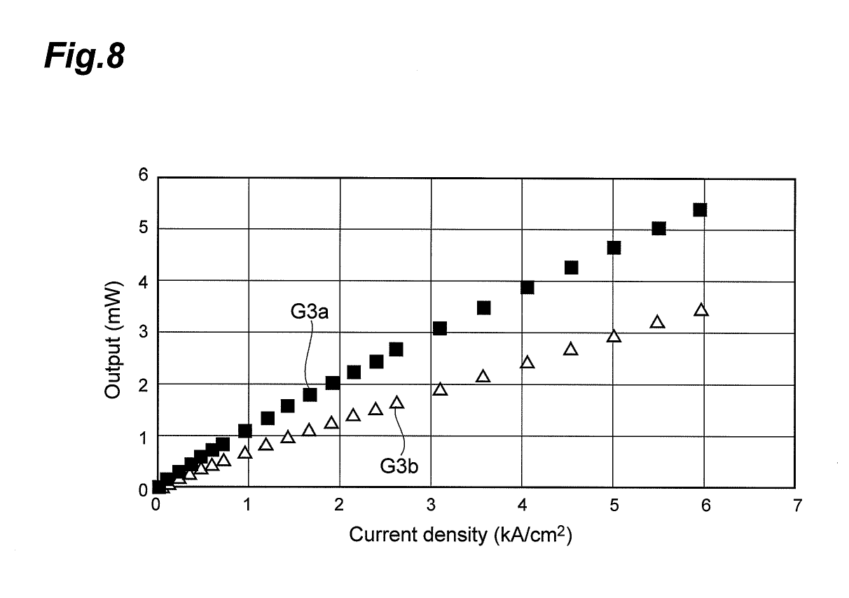

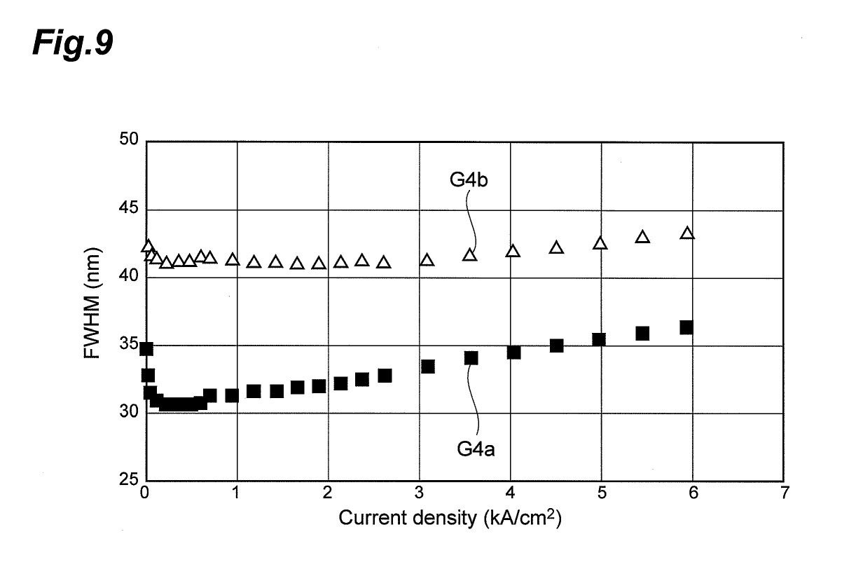

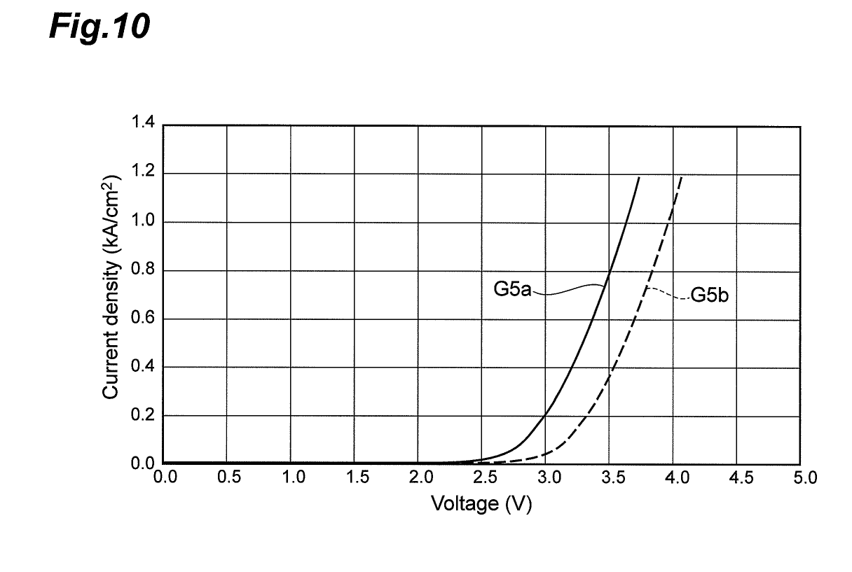

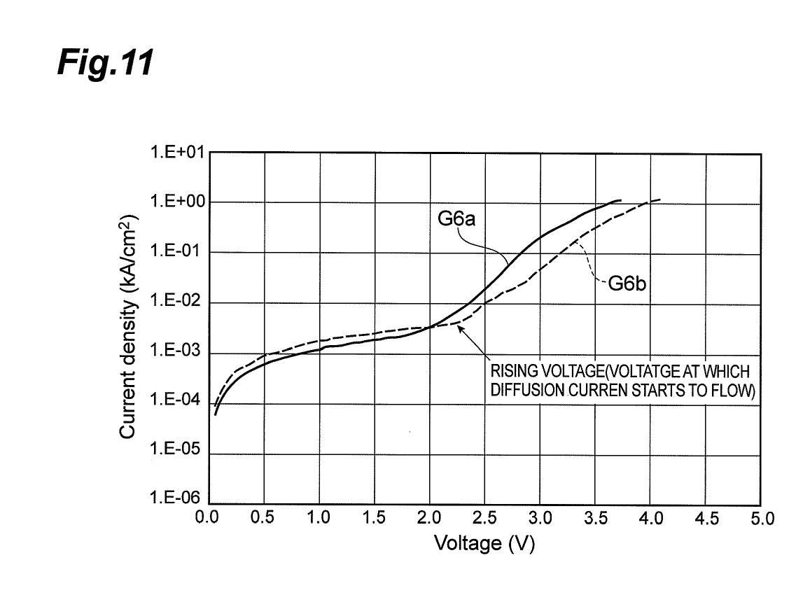

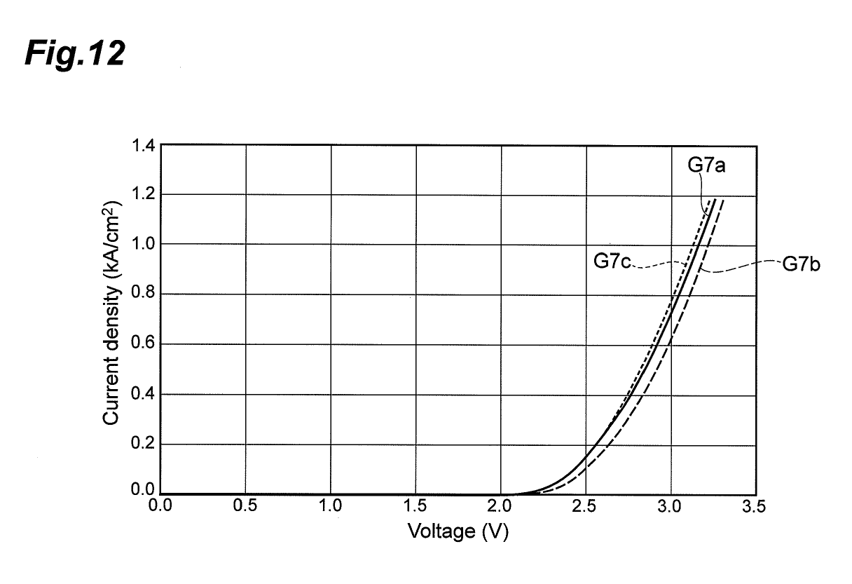

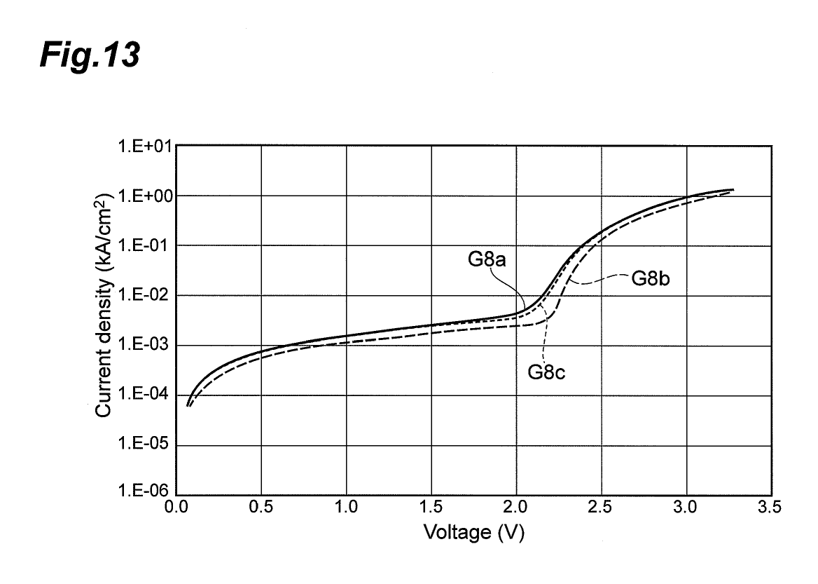

Experimental Example 1 will now be discussed with reference to FIGS. 7 to 11. FIG. 7 illustrates the results of the dependency of the emission wavelength on current density observed in Experimental Examples 1 and 6. FIG. 8 illustrates the results of the dependency of the output power on current density observed in Experimental Examples 1 and 6. FIG. 9 illustrates the observed results on the dependency of the full-width half-maximum of the emission wavelength on current density in Experimental Examples 1 and 6. FIGS. 10 and 11 illustrate the results of the IV characteristics observed in Experimental Examples 1 and 6. FIG. 12 illustrates the results of the IV characteristics observed in Experimental Examples 2 and 3 and Experimental Example 8, which is described below. FIG. 11 is the same as FIG. 10 except that the vertical axis (current density) is a logarithmic axis. FIG. 13 is the same as FIG. 12 except that the vertical axis (current density) is a logarithmic axis. The results illustrated in FIGS. 7 to 13 are obtained in Experimental Examples 1, 2, 3, 6, and 8 of an LED having a p-side electrode of a 100-μm by 100-μm palladium electrode and an n-side electrode of a Ti/Al/Ti/Au electrode provided on the entire back side. The results illustrated in FIGS. 7 to 9 are obtained by application of a pulsed current in Experimental Examples 1 and 6. The results illustrated in FIGS. 10 to 13 are obtained by application of a direct current in Experimental Examples 1, 2, 3, 6 and 8. The light-emitting device in Experimental Example 8 includes an LED having the same structure as that of Experimental Example 1, except that the light-emitting layer having a multiple quantum well structure is replaced with a light-emitting layer having a single quantum well structure.

In FIG. 7, the reference sign G2a represents the result of Experimental Example 1, and reference sign G2b represents the result of Experimental Example 6. At a low current density, the emission wavelength is shorter in Experimental Example 1 than in Experimental Example 6. This coincides with the results of the PL emission wavelength illustrated in FIG. 6. After the current density is increased to inject a relatively high current thereto, the difference between the emission wavelength in Experimental Example 1 and the emission wavelength in Experimental Example 6 decreases significantly into equivalent. This is presumed to be due to the cause of weakening of piezoelectric polarization in response to the current injection and, in Experimental Example 1, a reduction in the probability of transition between adjoining well layers due to screening. A light-emitting device formed on the c-plane including a barrier layer having a thickness of approximately 2.5 nm has low luminance efficiency. An InGaN layer grown over a semipolar surface, such as the (20-21) plane, in Experimental Example 1 is homogeneous and high quality. Thus, the luminance efficiency remains substantially unchanged with an extremely thin barrier layer.

In FIG. 8, reference sign G3a represents the result of Experimental Example 1, and reference sign G3b represents the result of Experimental Example 6. The results illustrated in FIG. 8 indicate that the output power is higher in Experimental Example 1 than Experimental Example 6. As described above, the PL luminance intensity is substantially the same in Experimental Examples 1 and 6. Thus, the quality of the well layers must be significantly different from each other. There is a difference between the output powers in Experimental Examples 1 and 6, as illustrated in FIG. 8 due to current injection, because Experimental Example 1 has higher carrier injection efficiency than Experimental Example 6.

Reference sign G4a in FIG. 9 represents the result of Experimental Example 1, and reference sign G4b represents the result of Experimental Example 6. The results illustrated in FIG. 8 indicate that the full-width half-maximum (FWHM) is smaller in Experimental Example 1 than Experimental Example 6. In particular, the difference between the FWHMs in Experimental Examples 1 and 6 is significant when the current density and the amount of electron injection are relatively small. In Experimental Example 6, it is believed that low carrier injection efficiency and a difference in the carrier density between the well layers cause an increase of the FWHM. An increase in the current density moderately reduces inhomogeneous injection in carrier density, thereby reducing the difference in the FWHMs between Experimental Examples 1 and 6, but not reducing the difference enough such that the FWHMs became substantially equal.

Reference sign G5a in FIG. 10 represents the results of Experimental Example 1, and reference sign G5b represents the results of Experimental Example 6. Reference sign G6a in FIG. 11 represents the results of Experimental Example 1, and reference sign G6b represents the results of Experimental Example 6. Referring to FIG. 10, the rising voltage of the current density at which a diffusion current starts to flow is smaller in Experimental Example 1 than Experimental Example 6. This also proves that the carrier injection efficiency is high in Experimental Example 1. Referring to FIG. 11, the rising voltage of the current density at which a diffusion current starts to flow is 2.4 volts in Experimental Example 1 and is 2.6 volts in Experimental Example 6.

The results in FIGS. 7 to 11 indicate that a relatively thin barrier layer (for example, approximately 2.5 nm) improves the electron injection efficiency in the light-emitting layer, even in negative piezoelectric polarization in the well layers. This also shortened the emission wavelength of light generated by weak excitation (“weak excitation” corresponds to a current density of 0.05 kA/cm² or less in the results illustrated in FIG. 7). Also, the rising voltage at which a diffusion current starts to flow is decreased. For example, the rising voltage can be decreased to 2.5 V or less. It is particularly preferable that the well layers and the barrier layer have substantially the same thickness in order to enhance both the carrier injection efficiency and the luminance efficiency. In this way, the light-emitting layer has excellent carrier injection efficiency and luminance efficiency at a shorter emission wavelength of light generated by weak excitation.

Experimental Examples 2 and 3 will now be discussed with reference to FIGS. 12 and 13. Reference sign G7a in FIG. 12 represents the results of Experimental Example 2, reference sign G7b represents the results of Experimental Example 3, and reference sign G7c represents the results of Experimental Example 8. Reference sign G8a in FIG. 13 represents the results of Experimental Example 2, reference sign G8b represents the results of Experimental Example 3, and reference sign G8c represents the results of Experimental Example 8. The rising voltage at which a diffusion current starts to flow was 2.3 volts in Experimental Example 2 and is 2.2 volts in Experimental Example 3. The rising voltages in Experimental Examples 2 and 3 are lower than the rising voltage of 2.4 volts in Experimental Example 1 (refer to FIG. 10) and are similar to the rising voltage of 2.2 volts of the single quantum well structure in Experimental Example 8. The results illustrated in FIGS. 12 and 13 suggest the carrier injection efficiency can be enhanced by the following: a reduction in the band gap energy of the entire barrier layer in Experimental Example 2; and a low electron barrier formed as a result of a band structure having a graded composition that alleviates the band bending caused by piezoelectric polarization in Experimental Example 3.

In Experimental Examples 1 and 4, cross-sectional TEM observation is performed to measure misfit dislocations. The cross-sectional TEM observation performed in Experimental Example 4 shows that the density of misfit dislocations is approximately 2×10⁴ cm⁻¹ at the interface between the n-InGaN layer having a thickness of approximately 150 nm and n-GaN layer having a thickness of approximately 200 nm, which are included in the n-side guiding layer. In contrast, misfit dislocations are not found at the same location in Experimental Example 1. Thus, the indium composition is relatively large in the n-side guiding layer in Experimental Example 4, which relaxes the InGaN layer having a thickness of approximately 150 nm in the n-side guiding layer relative to the support base, alleviating the strain incorporated in the light-emitting layer.

Experimental Example 4 will now be discussed. A pulsed current is applied to the LDs in Experimental Example 1 and 4 to evaluate the laser characteristics. The Ith (current threshold) in Experimental Example 1 is 85 mA, and the Ith in Experimental Example 4 is 60 mA. The Ith in Experimental Example 4 is smaller than the Ith in Experimental Example 1. Experimental Example 4 suggests that the relaxation of the n-InGaN layer having a thickness of approximately 150 nm in the guiding layer slightly weakens the piezoelectric polarization in the well layers to enhance the carrier injection efficiency. It is presumed that homogeneous injection of carriers into the well layers enhanced the luminance efficiency, as well as a reduction in the internal loss (non-homogeneous injection of carriers causes a well layer among the multiple well layer to have a low carrier density, which makes the well layer with a low carrier density non-transparent to absorb light from other well layers). Experimental Example 4 suggests that the relatively high optical confinement due to the relatively large indium composition of the n-InGaN layer having a thickness of approximately 150 nm in the guiding layer is one of the causes of the Ith in Experimental Example 4 being smaller than the Ith in Experimental Example 1.

As a result of measurements in Experimental Example 4, the PL emission wavelength is 527 nm, and the lasing wavelength is 522 nm. As a result of measurements in Experimental Example 1, the PL emission wavelength is 525 nm, and the lasing wavelength is 517 nm. The piezoelectric polarization in a light-emitting device formed on a semipolar primary surface, such as a (20-21) plane, is not zero. The relatively small difference between the PL emission wavelength and the lasing wavelength even with the presence of piezoelectric polarization suggests that, in at least Experimental Examples 1 and 4, the relatively thin barrier layer increase the probability of transition across adjoining well layers at measurement of the PL emission wavelength (refer to the results illustrated in FIG. 6). Such an increase in the probability of transition enhances the carrier injection efficiency. As actually confirmed through Experimental Examples 1 and 4, the blue-shift observed in a light-emitting device having a structure with excellent carrier injection efficiency is 15 nm or less from the peak value of the electroluminescence (EL) emission wavelength at a current density of approximately 0.05 kA/cm² or the peak value of the PL emission wavelength at an excitation density equivalent to the peak value of the EL emission wavelength to the lasing wavelength.

As understood through the embodiments described above, the method of fabricating a nitride semiconductor light-emitting device may include the following steps. In a step of preparing substrates, substrates for evaluation, which each have a primary surface composed of a hexagonal nitride semiconductor, are prepared. The primary surface of each substrate for evaluation tilts of an angle larger than zero from the c-plane of the hexagonal nitride semiconductor. In the step of forming diode structures, diode structures each of which has a quantum well structure for evaluation constituted of a barrier layer for evaluation and a well layer for evaluation are grown over the primary surfaces of the substrates for evaluation so as to estimate the nitride semiconductor light-emitting device. The thicknesses of the barriers layers for evaluation are different from each other. In the step of measuring the PL spectrum, the PL spectrum of the quantum well structure for evaluation in each diode structure is measured. The barrier layers for evaluation in the quantum well structures for evaluation have different thicknesses. Thus, the relationship between the peak wavelengths of PL spectra and the thicknesses of barrier layers in quantum well structures for evaluation can be determined. An example of such a relationship is illustrated in FIG. 6. In the determining step, the thickness of a barrier layer for the nitride semiconductor light-emitting device is determined from the dependency of the PL peak wavelength on the thickness of the barrier layer. In the step of forming an epitaxial substrate, a diode structure that includes a barrier layer having the determined thickness and a well layer and has a quantum well structure for the nitride semiconductor light-emitting device is grown on the primary surface of the substrate for a nitride semiconductor light-emitting device to from an epitaxial substrate for a nitride semiconductor light-emitting device. In the subsequent electrode-forming step, an electrode or electrodes are formed on the epitaxial substrate. The electrode(s) includes, for example, at least one of an anode and a cathode. The primary surface of the substrate may tilt at an angle larger than zero from the c-plane of the hexagonal nitride semiconductor, in a manner similar to the primary surfaces of the substrates for evaluation. In an example, the tilt angle of the primary surface may be within the range of 50 to 80 degrees or 130 to 170 degrees.

Referring to FIG. 6, the peak wavelength of the PL spectrum first decreases and then increases as the thickness of the barrier layer decreases. The thickness of the barrier layer for the nitride semiconductor light-emitting device can be determined on the basis of the dependency of the PL peak wavelength on the thickness of the barrier layer. A quantum well structure that includes a barrier layer having the thickness determined in this way has a small driving voltage for light emission. The thickness of the well layer may be within the range of 1 to 5 nm. A nitride semiconductor light-emitting device can be fabricated through the method according to the embodiment described with reference to FIGS. 3 and 4. The nitride semiconductor light-emitting device may include one of a laser diode and a light-emitting diode.

For example, the following nitride semiconductor light-emitting device can be fabricated through this method. The nitride semiconductor light-emitting device may include a support base and a diode structure. The support base has a primary surface composed of a hexagonal nitride semiconductor. The diode structure is formed on the primary surface of the support base. The diode structure includes a first-conductivity-type group-III nitride semiconductor layer provided on the primary surface of the support base, a light-emitting layer provided on the first-conductivity-type group-III nitride semiconductor layer, and a second-conductivity-type group-III nitride semiconductor layer provided on the light-emitting layer. The light-emitting layer has a multiple quantum well structure including first and second well layers and a barrier layer. The first and second well layers have compressive strain incorporated therein, and the direction of the piezoelectric polarization in the first and second well layers is the same as the direction from the p-region to the n-region on the diode structure. The primary surface tilts by an angle larger than zero from the c-plane of the hexagonal nitride semiconductor. The tilt angle of the primary surface may be within the range of 50 to 80 degrees or 130 to 170 degrees. The nitride semiconductor light-emitting device may include one of a laser diode and a light-emitting diode.

The thickness of the barrier layer is, for example, (DW−0.50) nm or more and (DW+0.50) nm or less, where DW represents the thickness of the well layers. The thickness DW of the well layers may be within the range of 1 to 5 nm.

The thickness of the barrier layer may be smaller than or equal to the thickness of the well layers. The thickness of the well layers may be within the range of 1 to 5 nm.

The thickness of the barrier layer in the nitride semiconductor light-emitting device may be 4.5 nm or less.

The nitride semiconductor light-emitting device is disposed over the diode structure and may further include a stripe electrode that extends along a reference plane defined by the c-axis and the m-axis of the hexagonal nitride semiconductor. The stripe electrode may include ohmic electrodes that are in ohmic contact with the surface of the diode structure and is composed of, for example, palladium.

The diode structure of the nitride semiconductor light-emitting device may include a ridge structure. The ridge structure may extend along the reference plane defined by the c-axis and the m-axis of the hexagonal nitride semiconductor.

In a first example, the barrier layer includes an InGaN layer, which has a indium composition profile monotonically changed along a direction from a first well layer to a second well layer, to lower the barrier against electrons. The indium composition profile increases, for example, in a direction from the p-region to the n-region on the diode structure.

In a second example, the diode structure may further include a optical guiding layer in contact with the first well layer. The first well layer is in contact with the barrier layer, and the barrier layer is in contact with the second well layer. The band gap of the group-III nitride semiconductor of the barrier layer is smaller than the band gap of the group-III nitride semiconductor of the optical guiding layer in contact with the quantum well structure, lowering the barrier against electrons.

In a third example, the diode structure may further include a optical guiding layer provided between a light-emitting layer and a support base. The optical guiding layer includes a GaN guiding layer and an InGaN guiding layer. The GaN guiding layer is in contact with the InGaN guiding layer to form an interface. When the indium composition of the InGaN guiding layer is within the range of 0.02 to 0.06 and the thickness of the InGaN guiding layer is within the range of 100 to 500 nm, the interface has misfit dislocations that have a certain influence on the strain of the light-emitting layer. The misfit dislocation density may be within the range of 5×10³ to 1×10⁵ cm⁻¹. The strain of the light-emitting layer is alleviated by the formation of a c-plane slip plane, and the piezoelectric field of the well layers of the light-emitting layer is decreased. The relaxation of the strain lowers the barrier generated by the piezoelectric field. Thus, the barrier against electrons can be lowered. An InGaN guiding layer that achieves a misfit dislocation density smaller than 5×10³ cm⁻¹ has an indium composition within the range of 0.01 to 0.02 and a thickness within the range of 50 to 200 nm.

This embodiment provides a nitride semiconductor light-emitting device that is disposed over a semipolar plane and has a low bias voltage for light emission and a method of fabricating the nitride semiconductor light-emitting device.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A nitride semiconductor light-emitting device comprising:
a support base comprising a hexagonal nitride semiconductor and having a primary surface, the primary surface tilting in a predetermined direction away from a c-plane of the hexagonal nitride semiconductor;
an n-type gallium nitride-based semiconductor layer provided on the primary surface of the support base;
a light-emitting layer, comprising a gallium nitride-based semiconductor, provided on the n-type gallium nitride-based semiconductor layer; and
a p-type gallium nitride-based semiconductor layer provided on the light-emitting layer,
the light-emitting layer having a multiple quantum well structure,
the multiple quantum well structure comprising at least two well layers and at least one barrier layer,
the barrier layer being provided between the well layers,
the well layers comprising InGaN,
the well layers having a first indium composition in a range of 0.15 to 0.50,
a tilt angle formed between the c-plane and the primary surface being in a range of 50 to 80 degrees or 130 to 170 degrees, and
the barrier layer having a thickness in a range of 1.0 to 4.5 nm.

2. The nitride semiconductor light-emitting device according to claim 1, wherein the thickness of the barrier layer is not more than a value which the thickness of the well layers plus 0.50 nm equals, and the thickness of the barrier layer is not less than a value which the thickness of the well layers minus 0.50 nm equals.

3. The nitride semiconductor light-emitting device according to claim 1, wherein
the barrier layer comprises InGaN, and
the barrier layer has a second indium composition in a range of 0.01 to 0.10.

4. The nitride semiconductor light-emitting device according to claim 1, wherein
the n-type gallium nitride-based semiconductor layer has an InGaN layer,
the light-emitting layer is provided on the InGaN layer,
the InGaN layer in the n-type gallium nitride-based semiconductor layer includes misfit dislocations at a nearer interface thereof, and the nearer interface is situated nearer the support base in relation to the InGaN layer,
the misfit dislocations extend in a direction orthogonal to a reference axis and a c-axis of the hexagonal nitride semiconductor, the reference axis is defined by a line of intersection of the nearer interface of the InGaN layer and a reference plane orthogonal to the nearer interface of the InGaN layer, and the reference plane contains the c-axis of the hexagonal nitride semiconductor, and
a density of the misfit dislocations is in a range of 5×10³ to 1×10⁵ cm⁻¹.

5. The nitride semiconductor light-emitting device according to claim 4, wherein the InGaN layer has a third indium composition in a range of 0.03 to 0.05.

6. The nitride semiconductor light-emitting device according to claim 3, wherein the second indium composition increases in a direction from the p-type gallium nitride-based semiconductor layer to the n-type gallium nitride-based semiconductor layer.

7. The nitride semiconductor light-emitting device according to claim 1, wherein a tilt angle formed between the c-plane and the primary surface is in a range of 63 to 80 degrees.

8. The nitride semiconductor light-emitting device according to claim 1, wherein the first indium composition is in a range of 0.24 to 0.40.

9. The nitride semiconductor light-emitting device according to claim 3, wherein the second indium composition is in a range of 0.01 to 0.06.

10. The nitride semiconductor light-emitting device according to claim 1, wherein the thickness of the barrier layer is within a range of 1.0 to 3.5 nm.

11. A method of fabricating a nitride semiconductor light-emitting device comprising the steps of:
preparing a substrate, the substrate comprising a hexagonal nitride semiconductor and having a primary surface, the primary surface tilting in a predetermined direction with respect to a c-plane of the hexagonal nitride semiconductor;
growing an n-type gallium nitride-based semiconductor layer on the primary surface of the substrate;
growing a light-emitting layer on the n-type gallium nitride-based semiconductor layer, the light-emitting layer comprising a gallium nitride-based semiconductor; and
growing a p-type gallium nitride-based semiconductor layer on the light-emitting layer,
the light-emitting layer including a first well layer, a second well layer, and a barrier layer,
in the step of growing the light-emitting layer, the first well layer, the barrier layer, and the second well layer being grown, in sequence, on the n-type gallium nitride-based semiconductor layer,
the first well layer and the second well layer comprising InGaN,
the first well layer and the second well layer having a first indium composition in a range of 0.15 to 0.50,
a tilt angle formed between the c-plane and the primary surface being in a range of 50 to 80 degrees or 130 to 170 degrees, and
the barrier layer having a thickness in a range of 1.0 to 4.5 nm.

12. The method of fabricating a nitride semiconductor light-emitting device according to claim 11, wherein the thickness of the barrier layer is not more than a value which the thickness of the well layers plus 0.50 nm equals, and the thickness of the barrier layer is not less than a value which the thickness of the well layers minus 0.50 nm equals.

13. The method of fabricating a nitride semiconductor light-emitting device according to claim 11, wherein
the barrier layer comprises InGaN, and
the barrier layer has a second indium composition in a range of 0.01 to 0.10.

14. The method of fabricating a nitride semiconductor light-emitting device according to claim 11, wherein
the n-type gallium nitride-based semiconductor layer includes an InGaN layer,
the light-emitting layer is grown on the InGaN layer,
the n-type gallium nitride-based semiconductor layer contains misfit dislocations on a nearer surface of the InGaN layer, and the nearer surface is situated nearer the support base in relation to the n-type gallium nitride-based semiconductor layer,
the misfit dislocations extend in a direction orthogonal to a reference axis and the c-axis of the hexagonal nitride semiconductor, the reference axis is defined by a line of intersection of the nearer interface of the InGaN layer with a reference plane orthogonal to the nearer interface of the InGaN layer, and the reference plane contains the c-axis of the hexagonal nitride semiconductor, and
a density of the misfit dislocations is in a range of 5×10³ to 1×10⁵ cm⁻¹.

15. The method of fabricating a nitride semiconductor light-emitting device according to claim 14, wherein the InGaN layer has a third indium composition in a range of 0.03 to 0.05.

16. The method of fabricating a nitride semiconductor light-emitting device according to claim 13, wherein the second indium composition increases in a direction from the p-type gallium nitride-based semiconductor layer to the n-type gallium nitride-based semiconductor layer.

17. The method of fabricating a nitride semiconductor light-emitting device according to claim 11, wherein a tilt angle formed between the c-plane and the primary surface is in a range of 63 to 80 degrees.

18. The method of fabricating a nitride semiconductor light-emitting device according to claim 11, wherein the first indium composition is in a range of 0.24 to 0.40.

19. The method of fabricating a nitride semiconductor light-emitting device according to claim 13, wherein the second indium composition is in a range of 0.01 to 0.06.

20. The method of fabrication a nitride semiconductor light-emitting device according to claim 11, wherein the thickness of the barrier layer is within a range of 1.0 to 3.5 nm.

21. A method of fabrication a nitride semiconductor light-emitting device comprising the steps of:
preparing first substrates for evaluation, each first substrate having a primary surface, the primary surface comprising a hexagonal nitride semiconductor;
forming first diode structures on the primary surfaces of the first substrates in order to estimate the nitride semiconductor light-emitting device, the first diode structures having first quantum well structures for evaluation, each quantum well structure including a first barrier layer for evaluation and a first well layer for evaluation;
measuring photoluminescence spectra of the first quantum well structures in the first diode structures and determining a relationship between peak wavelengths of the photoluminescence spectra and thicknesses of the barrier layers of the first quantum well structures;
determining a thickness for a second barrier layer for a nitride semiconductor light-emitting device based on the relationship; and
growing a second diode structure on a primary surface of a second substrate to form an epitaxial substrate, the second diode structure including a second quantum well structure for the nitride semiconductor light-emitting device, the second quantum well structure including a second well layer and a second barrier layer, and the second barrier layer having the determined thickness,
the primary surfaces of the first substrates and the primary surface of the second substrate each having semi-polarity and tilting at an angle larger than zero with respect to a c-plane of the hexagonal nitride semiconductor thereof, and
the first barrier layers having thicknesses different from each other.

22. The method of fabrication a nitride semiconductor light-emitting device according to claim 21, wherein the nitride semiconductor light-emitting device includes one of a laser diode and a light-emitting diode.

23. The method of fabrication a nitride semiconductor light-emitting device according to claim 21, wherein the thickness of the second barrier layer is not less than (DW−0.50) nm and not more than (DW+0.50) nm, where DW represents the thickness of the second well layer.

24. The method of fabrication a nitride semiconductor light-emitting device according to claim 21, wherein the thickness of the second barrier layer is smaller than the thickness of the second well layer.

25. A nitride semiconductor light-emitting device comprising:
a support base having a primary surface, the primary surface comprising a hexagonal nitride semiconductor; and
a diode structure provided on the primary surface of the support base,
the diode structure including a first conductivity type group-III nitride semiconductor layer, a light-emitting layer, and a second conductivity type group-III nitride semiconductor layer, the first conductivity type group-III nitride semiconductor layer being provided on the primary surface of the support base, the light-emitting layer being provided on the first conductivity type group-III nitride semiconductor layer, and the second conductivity type group-III nitride semiconductor layer being provided on the light-emitting layer,
the light-emitting layer having a multiple quantum well structure, the multiple quantum well structure including a first well layer, a second well layer, and a barrier layer,
the primary surface having semi-polarity and tilting at a tilt angle larger than zero with respect to a c-plane of the hexagonal nitride semiconductor,
the tilt angle of the primary surface being in a range of 50 to 80 degrees or 130 to 170 degrees, and
the thickness of the barrier layer being 4.5 nm or less.

26. The nitride semiconductor light-emitting device according to claim 25, further comprising one of a laser diode and a light-emitting diode.

27. The nitride semiconductor light-emitting device according to claim 25, further comprising a stripe electrode provided on the diode structure, the stripe electrode extending along a reference plane, and the reference plane being defined by a c-axis and an m-axis of the hexagonal nitride semiconductor.

28. The nitride semiconductor light-emitting device according to claim 25, wherein the diode structure has a ridge structure extending along a reference plane defined by a c-axis and an m-axis of the hexagonal nitride semiconductor.

29. The nitride semiconductor light-emitting device according to claim 25, wherein
the barrier layer includes an InGaN layer,
the InGaN layer has a indium composition monotonically changing in a direction from the first well layer to the second well layer, and
the indium composition increases in a direction from a p-region to an n-region of the diode structure.

30. The nitride semiconductor light-emitting device according to claim 25, further comprising an optical guiding layer in contact with the first well layer,
the first well layer being in contact with the barrier layer,
the barrier layer being in contact with the second well layer, and
a band gap of a first group-III nitride semiconductor of the barrier layer being smaller than a band gap of a second group-III nitride semiconductor of the optical guiding layer.
